(19) United States
(12) Patent Application Publication
(10) Pub. No.: US 2026/0241333 A1
(43) Pub. Date: Aug. 20, 2026

(54) EFFICIENT ATMOSPHERIC WATER GENERATION SYSTEMS AND METHODS WITH DATA CENTER INTEGRATION

(71) Applicant: GENESIS SYSTEMS LLC, Tampa, FL (US)

(72) Inventors: Shannon Stuckenberg, Tampa, FL (US); David Stuckenberg, Tampa, FL (US); Jonathan Merheb, Tampa, FL (US); Zach Mixson, Tampa, FL (US); Owen Erickson, Largo, FL (US)

(21) Appl. No.: 19/541,947

(22) Filed: Feb. 17, 2026

Related U.S. Application Data
(60) Provisional application No. 63/759,834, filed on Feb. 18, 2025.

(51) Int. Cl. B01D 53/26; B01D 53/04; B01D 53/06; B01D 53/14; B01J 20/22; B01J 20/34; H05K 7/20

(52) U.S. Cl. CPC B01D 53/263; B01D 53/0438; B01D 53/0454; B01D 53/06; B01D 53/1412; B01D 53/1425; B01J 20/226; B01J 20/3425; B01J 20/3458; H05K 7/20263; H05K 7/20781; B01D 2253/204; B01D 2257/504; B01D 2257/80; B01D 2258/06; B01D 2259/4009

(57) ABSTRACT

An integrated data center resource system includes an absorption cooling subsystem thermally coupled to a hot exhaust stream and configured to produce chilled coolant for cooling data center equipment. A desiccant-based water harvesting subsystem receives at least a portion of the hot exhaust stream to regenerate a moisture-absorbing desiccant, extract water vapor from ambient air, and release and condense liquid water. A carbon capture subsystem downstream of the cooling and water harvesting subsystems removes carbon dioxide from cooled exhaust gas. A control system dynamically allocates the hot exhaust stream among the subsystems to simultaneously provide cooling, recover water, and reduce carbon emissions.

### CROSS-REFERENCE TO RELATED APPLICATIONS

This application claims priority to U.S. Provisional Application No. 63/759,834, filed on Feb. 18, 2025, the contents of which are hereby incorporated by reference in their entirety.

### FIELD OF INVENTION

The present disclosure relates to atmospheric water generation systems, and more particularly to an integrated system for efficient water extraction, cooling, and carbon capture that can be used with data center environments.

### BACKGROUND

Data centers are facilities that house computer systems and associated components for storing, processing, and distributing large amounts of data. As the demand for digital services continues to grow, so does the need for more and larger data centers. However, these facilities face several challenges related to resource consumption and environmental impact.

One of the primary concerns for data centers is cooling. The dense arrangement of servers and other computing equipment generates significant heat, which must be removed to maintain optimal operating conditions. Traditional cooling methods often rely on energy-intensive air conditioning systems, contributing to high electricity usage and increased operational costs.

Water usage is another critical factor in data center operations. Many cooling systems require substantial amounts of water, either for direct cooling or for evaporative cooling towers. This water consumption can strain local water resources, particularly in areas prone to drought or water scarcity.

Therefore, a need exists for novel and low-resource solutions for providing cooling for data centers.

### BRIEF DESCRIPTION OF FIGURES

Non-limiting and non-exhaustive examples are described with reference to the following figures.

FIG. 1A illustrates a water generation system that processes ambient air to extract water, according to aspects of the present disclosure.

FIG. 1B illustrates a system diagram of a water extraction and processing system, according to an embodiment.

FIGS. 2A-2C illustrate different views of a membrane-based extraction device, according to aspects of the present disclosure.

FIGS. 2D-2E illustrate cross-sectional views of membrane-based water extraction configurations, according to an embodiment.

FIG. 3 illustrates a system diagram of an atmospheric water generation system integrated with a data center and power plant, according to aspects of the present disclosure.

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

### Water Extraction from Air using Desiccant Processes

Harvesting water from ambient air via desiccants is a well-established technique. Atmospheric water generators (AWGs) often employ either solid desiccant wheels or liquid desiccant solutions to absorb moisture, then use heat to release and condense the water. For example, systems that use a desiccant to pull moisture from air and regenerate it using waste heat from engines have been developed. One design uses a desiccant wheel in an air loop, heated by a vehicle. Another uses a liquid desiccant heated by engine exhaust to extract water. These designs achieve water production with minimal external energy by leveraging available heat. Recent innovations further optimize desiccant-based AWGs with staged heating/cooling of desiccants to boost efficiency. However, these systems are typically standalone water generators or vehicle-mounted units. They do not contemplate integration with data center power systems and thus may not fully optimize synergies with on-site waste heat or cooling needs. There is a risk that directly adopting such a process in a new design could infringe existing patents. Therefore, any new design must either use these concepts under license or introduce a novel configuration that avoids the specific patented methods (for instance, by using a different desiccant cycle or unique heat exchange arrangement).

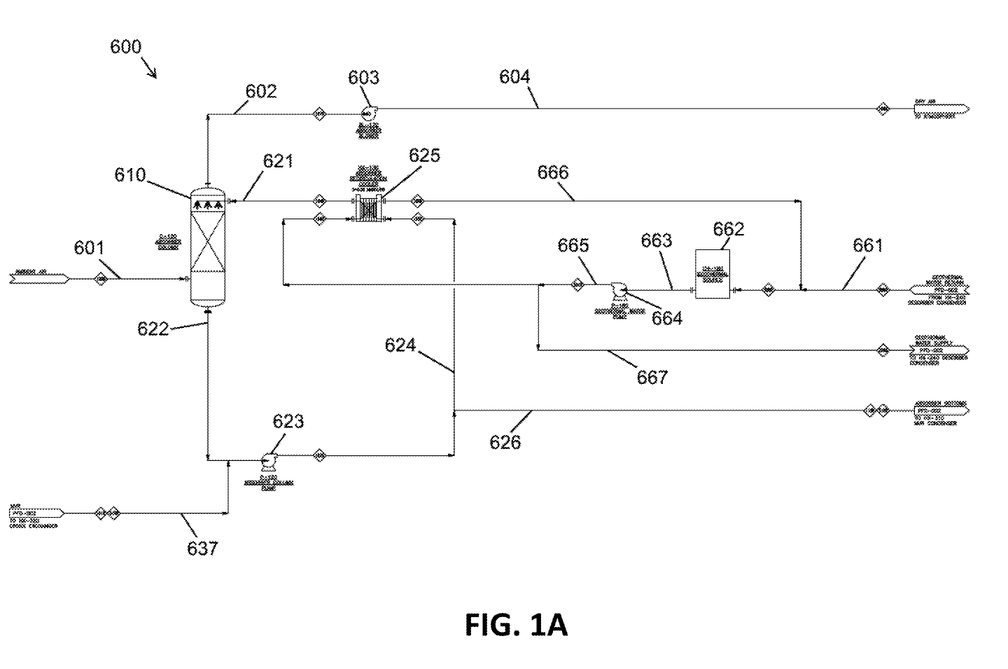

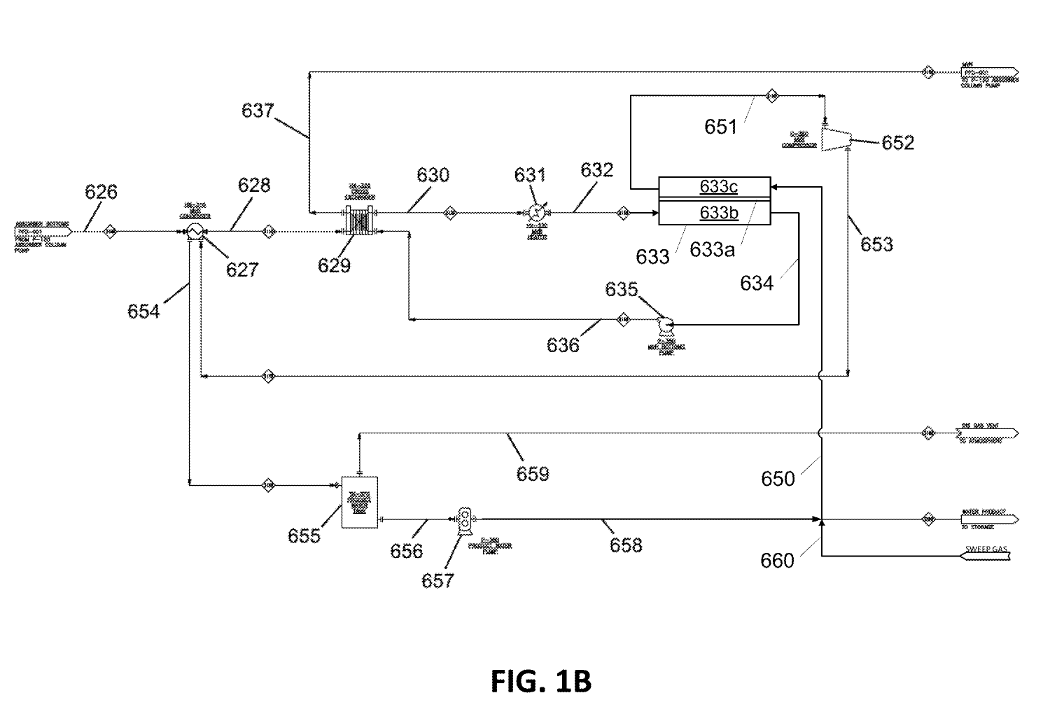

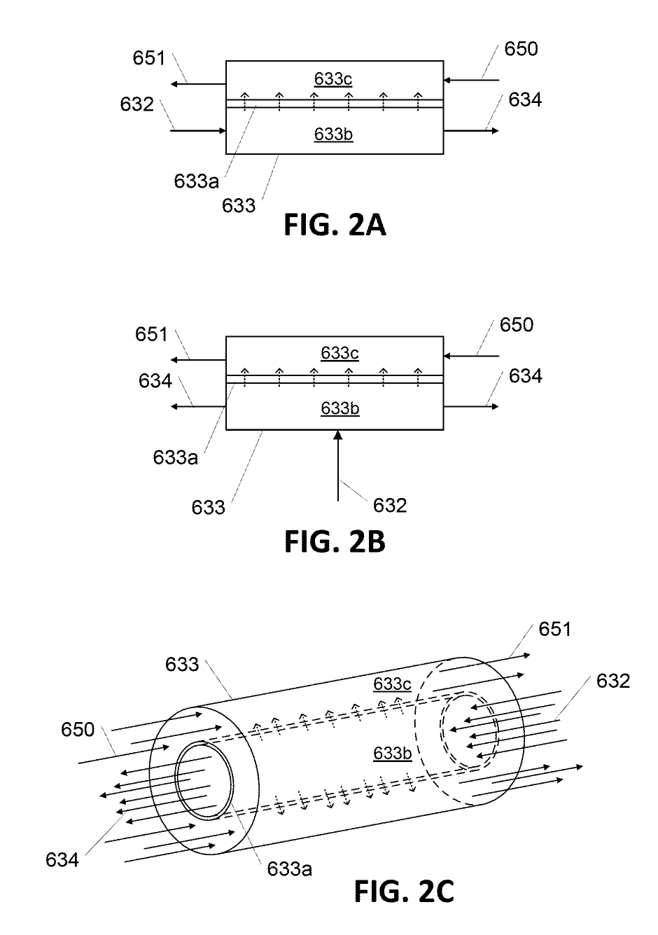

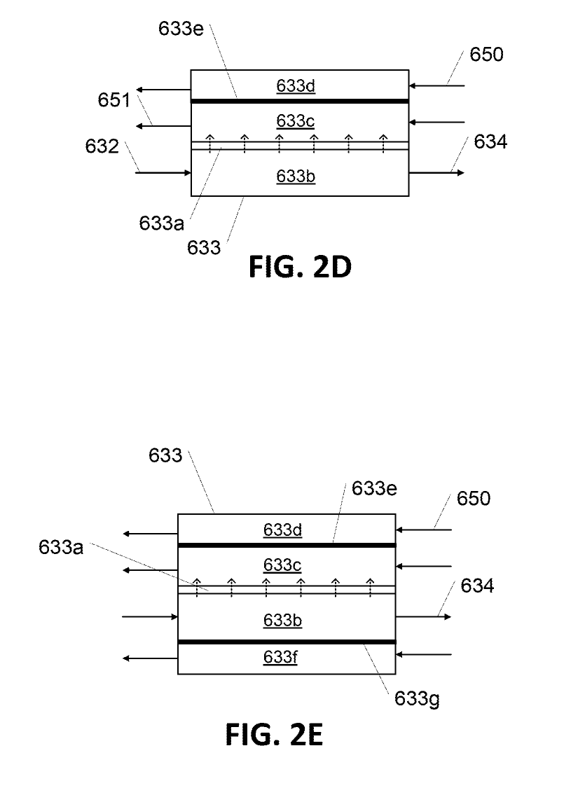

FIGS. 1A-2E illustrate various components of an AWG system according to certain embodiments. It should be understood that the AWG system illustrated in FIGS. 1A-2E, and the corresponding description is provided merely as an example, and other AWG systems may be utilized in certain embodiments.

### Air Preconditioning

Raw source air may be preconditioned to ease the water extraction process utilized to ultimately condense water vapor into usable liquid water. In certain embodiments, the preconditioning process may comprise steps for compressing the air to increase the vapor pressure of the air (thereby biasing a greater volume of water to the liquid state rather than the vapor state) and/or to decrease the temperature of the source air to a temperature nearer to the dew point. In certain embodiments, an air preconditioning system described herein may be utilized before and/or after a humidity increasing system, such as a desiccant-based humidity increasing system as described herein. Moreover, the air preconditioning system may be utilized before and/or after a carbon dioxide capture system as discussed herein.

As just one example, the air preconditioning process may comprise a series of compressors/pumps, venturi valves, vortex valves, manifolds, and/or the like collectively configured to decrease the temperature of the source air closer to the air dew point and/or to increase the pressure of the air prior to removing water vapor from the air (e.g., through condensation or absorption by a desiccant). For example, raw source air may be drawn into the air preconditioning system via a vacuum pressure formed at an inlet via a compressor 101 (e.g., a turbine/blower compressor having a plurality of stator or variable pitch turbine blades controllable via servo motors) and/or a centrifugal fan configured to increase the raw air pressure entering the air preconditioning system. In certain embodiments, the compressor and/or centrifugal fan may be rotated via one or more electrical motors (which may receive electrical input power from one or more power systems in communication with the air preconditioning system) mechanically connected with the compressor and/or centrifugal fan via a gear transmission, a belt drive, a chain drive, and/or the like.

In embodiments comprising a centrifugal fan, particulates, dust, and other heavy air contaminants are spun to the outermost edge of the centrifugal fan and are removed from the air stream and ejected from the air preconditioning system.

In certain embodiments, the filtered air may be directed into a carbon dioxide capture column, where it is passed over a fixed absorption bed configured to absorb carbon dioxide from the air, as discussed in greater detail herein. The carbon dioxide may be separated and directed away from the air stream via a compressor.

In certain embodiments, the filtered air (with a reduced carbon dioxide content) may be directed further through the air preconditioning system into a primary manifold, where the air is divided at a selected ratio by a variable plenum/valve. From the primary manifold, a first air stream continues along a bulk air stream, and a second air stream is directed to a vortex tube manifold as discussed herein.

The bulk air stream may proceed through one or more venturi valves each configured to decrease the pressure and temperature of the bulk air stream (the volume and quantity of air remains constant across each venturi valve while the pressure decreases, thereby causing the temperature of the air stream to decrease proportionally to the temperature) and/or through a precooler (e.g., a heat exchanger with a cooling fluid passing therethough). After proceeding through the one or more venturi valves and/or the precooler, the bulk air stream may proceed to a temperature measurement portion, where the temperatures (e.g., dry bulb and wet bulb temperatures) of the bulk air stream are measured by one or more temperature measurement devices (e.g., thermometers) to determine the dew point of the bulk air stream. Outputs from the temperature measurement devices may be utilized by a controller to mix the bulk air stream with at least a portion of the vortex-chilled air stream to lower the temperature of the bulk air closer to the air dew point. For example, the controller may be in electronic communication with an electromechanical mixing valve that may be selectably opened or closed to vary the amount of vortex-chilled air that is introduced into the bulk air stream. Based on the determined dry-bulb and/or wet-bulb temperatures (as monitored by the controller), the controller may transmit a signal to a motor to move the electromechanical valve to a desired position to obtain a desired mixture of vortex-chilled air with the bulk air stream.

The vortex-chilled air begins as the second stream of air exiting the primary manifold. The second stream of air exits the primary manifold, and proceeds to a vortex tube manifold where it is pressurized (e.g., via a compressor) to a sufficient pressure to achieve a drop in temperature of the air travelling through one or more vortex tubes 106 of between approximately 70-150 degrees Fahrenheit. For example, the air may be pressurized to at least approximately 70-120 PSI prior to being directed into the one or more vortex tubes. Each vortex tube comprises an entry port directing the stream of air tangentially into an internal spin chamber. As air enters the spin chamber, the air takes on an angular momentum, causing dense, warm air to migrate towards an exterior perimeter of the spin chamber and out of an exhaust valve. In certain embodiments, the warm air may be utilized to heat a carbon dioxide capture column. The remaining, vortex-chilled air migrates toward the center of the spin chamber and out of a vortex outlet. As mentioned above, the vortex-chilled air may be mixed with the bulk air stream to lower the temperature of the bulk air stream closer to the dew point. As yet another alternative, the vortex chilled air may be utilized to chill the precooler through which the bulk air passes.

In certain embodiments, the mixed and chilled bulk air stream is then directed into a condensation chamber, where the water vapor within the air is condensed into liquid water. As just one example, the bulk air stream may be directed over a series of condensation surfaces (e.g., chilled plates, screens, tubes, and/or the like configured to lower the localized temperature of the air at the condensation surfaces below the air dew point, thereby causing the water vapor to condense on the condensation surfaces. The condensed water may then be routed from the condensation surfaces into a retention chamber for collection and later use. However, it should be understood that any of a variety of condensation mechanisms may be used. For example, as discussed herein, one or more desiccant-based condensation mechanisms may be utilized to more effectively remove water vapor from the bulk air stream. Moreover, in certain embodiments the air-preconditioning system may be omitted, and raw air may be filtered and/or directed immediately into a condensation chamber. Such embodiments may have a lower input power requirement, and therefore the amount of power required for water generation may be decreased.

It should also be understood that certain preconditioning system embodiments comprise one or more filters (e.g., fabric-based air filters, non-woven based air filters, and/or the like), one or more refrigerant systems (e.g., warm air is passed through a heat-exchanger to lower the temperature of the air closer to the dew point), and/or the like in place of or in addition to the vortex and venturi valve mechanisms discussed herein.

### Desiccant-Usage within an Atmospheric Water Generation System

As mentioned above, certain embodiments comprise one or more subsystems configured to increase the humidity of a portion of the source air to increase the amount of water that may be extracted from the source air. Specifically, water vapor may be extracted from a first, large quantity of source air, and may be reintroduced into a second, smaller quantity of source air, thereby consolidating the water vapor of the source air and increasing the humidity of the second quantity of source air before the water vapor in the second quantity of source air is condensed into liquid water.

AWG systems as discussed herein comprise at least one air scrubber comprising a column for contacting atmospheric air (e.g., after increasing the humidity of the air) with a desiccant. In certain embodiments, the desiccant solution may be a fluid, a gel, and/or the like within the typical operating temperature ranges discussed herein. The desiccant may be selected from any of a variety of ionic solutions capable of absorbing water, such as lithium-chloride (LiCl), lithium-bromide (LiBr), Calcium Chloride (CaCl), triethylene glycol, and/or the like. Other, unlisted chemical compounds having hygroscopic characteristics may be provided for use as the desiccant solution in certain embodiments. The hygroscopic fluid may also be comprised of surfactants and/or nanofluids.In certain embodiments, the desiccant solution may comprise a mixture of a plurality of ionic solutions, such as a mixture of LiCl solution and CaCl solution, The desiccant may be dissolved in water to provide a highly concentrated desiccant solution that may be pumped (e.g., via liquid pumps) through the at least one desiccant column. Other materials, including gels, aerogels, desiccant granules flowable subject to granular flow principles, and/or the like may be utilized in place of desiccant solutions in certain embodiments. As discussed in greater detail herein, other embodiments utilize granulated desiccants in other AWG system configurations.

Moreover, the amount of water vapor that may be absorbed by the desiccant (and/or released by the desiccant) is dependent on the vapor pressure and temperature of a closed system including the desiccant. Accordingly, various embodiments are configured to absorb water from the air into the desiccant while the vapor pressure in the closed system is high and the temperature is low, and those same embodiments are configured to extract water from the desiccant while the vapor pressure is low and the temperature is high.

### Water Absorption from Atmospheric Air

Water may extracted from air via one or more absorption modules. AWG systems (an example of which is shown as system 600 shown in FIGS. 1A-1B) may incorporate a single absorption module or multiple absorption modules. The absorption modules are connected with additional modules within the AWG system, including the water extraction module(s) discussed in greater detail below, such that the desiccant can flow between the water absorption module and the additional modules of the AWG system. Flow paths to and from the absorption modules within the overall AWG system may be configurable (e.g., configurable via valves between open and closed configurations), such that the absorption modules can operate as closed-modules in a batch-operating mode (with the desiccant flowing only within the absorption module and/or between multiple absorption modules) prior to passing the desiccant to water extraction modules. In other embodiments (e.g., when valves are in an open configuration, or in embodiments without valves), the desiccant flows freely between the absorption module(s) and the water extraction module(s), such as in a continuous flow operating configuration.

Moreover, as mentioned, air entering the absorption module(s) (e.g., via air flow path 601 entering absorber 610 and exiting absorber as dry air via flow path 602-604 shown in FIG. 1A) may flow from a pre-conditioning module configured for increasing the humidity of atmospheric air prior to extracting water from the atmospheric air within the absorber 610. In other embodiments, air may flow directly into the absorption module(s) from the surrounding atmosphere external to the AWG system.

The absorption module according to certain embodiments comprises an absorber 610 configured to contact ambient/atmospheric air (e.g., after preconditioning) with a desiccant (flowing through the absorber 610 along flow paths 621-622) so as to absorb water from the atmospheric air into the desiccant. The absorber 610 may be embodied as a vessel in which the desiccant flows between an inlet (via flow path 621) and an outlet (via flow path 622), and the ambient/atmospheric air flows between an air inlet (flow path 601) and an air outlet (flow path 602-604, inclusive of blower 603). Within the vessel, the ambient air contacts the desiccant to enable mass transfer of water vapor from the ambient air into the desiccant. In certain embodiments, one or more baffles, flow interrupters, packings (e.g., structured packing or random packing) may be placed within the absorber so as to increase the surface area of the desiccant and/or to increase the contact time between the ambient air and the desiccant.

In certain embodiments the absorber 610 is configured in a counter flow configuration where atmospheric air enters the absorber 610 proximate to the bottom of the absorber 610. Dry, atmospheric air then exits the absorber 610 proximate the top of the absorber 610 via a specific flow path (with a pump/blower 603 utilized to move air through the absorber 610). Rich desiccant (e.g., a desiccant fluid) enters proximate the top of the absorber 610 via an inlet flow path 621 and flows down through the interior of the absorber 610 due to gravity. Water is absorbed from the ambient air into the desiccant, such that dilute desiccant exits the absorber proximate to the bottom of the absorber 610 along an outlet flow path 622. In certain embodiments, flow modifiers, such as barriers, mesh, packing components, and/or turns in exit piping from the absorber 610 may be used to reduce carry over of desiccant in the air exit of the absorber 610. In certain embodiments the flow modifiers may be positioned in the interior of the absorber 610 proximate to the top of the absorber 610 (e.g., at a mouth of an exhaust port for dry ambient air to exit the absorber via an exhaust air flow path).

In certain embodiments, the absorber 610 operates in a cross-flow configuration where air enters the absorber from one the side of the absorber 610 and traverses (e.g., at least substantially horizontally) to the other side. Rich desiccant (e.g., desiccant fluid) enters the top of the absorber 610, absorbs water from the ambient air as it flows to a low point in the absorber 610 where dilute desiccant exits proximate the bottom. In this fashion, the air flow is at least substantially perpendicular to the flow of desiccant within the absorber 610. In this configuration, the air inlet and air outlet are approximately at the same height on the absorber 610.

In certain configurations, the absorber 610 is operated in the cross-counter flow configuration where air enters the absorber 610 from one the side of the absorber 610 and traverses to the other side. Rich desiccant (e.g., desiccant fluid) enters proximate the top of the absorber 610 and absorbs water from the ambient air as it flows to a low point in the absorber 610 where dilute desiccant exits proximate the bottom of the absorber 610. In this configuration, the air inlet and air outlet are offset in level from each other. In this configuration, the air inlet can be at the side of the absorber 610 at a location proximate to the top of the absorber 610 and the air outlet is on the side of the absorber 610 proximate to the bottom. In another orientation of this configuration, the air inlet is positioned on the side of the absorber 610 proximate to the bottom of the absorber 610 and the air outlet is positioned on the opposite side of the absorber 610 proximate to the top of the absorber 610. The air travels along a path extending at an angle through the absorber 610 from the top of the absorber 610 to the bottom or the bottom of the absorber 610 to the top.

In use of an overall AWG system, ambient air (at an ambient temperature and an ambient humidity level) is directed into absorber 610 (although not shown, a blower may be implemented at the air intake to the absorber 610 to increase the volumetric flowrate of ambient air entering the absorber 610). In the absorber 610, the ambient air contacts a rich (concentrated) desiccant (e.g., desiccant fluid) provided to the absorber 610 at a low temperature, to increase the vapor pressure within the absorber to encourage water vapor within the humid ambient air to condense and to be absorbed by the desiccant fluid while the humid air contacts the rich desiccant. While the ambient air and the desiccant fluid flow through the absorber 610, humidity within the air condenses and/or is otherwise absorbed into the desiccant fluid to dilute the desiccant fluid and to dry the air. The dry air then exits the absorber back to the atmosphere, as indicated at 602. As shown, a blower 603 may be incorporated at an ambient air exhaust of the absorber 610 to increase the volumetric flowrate of air passing through the absorber 610. The blower 603 may be provided in addition to, or as an alternative to, the above-mentioned blower placed at the ambient air intake of the absorber 610. Moreover, once the desiccant fluid has passed through the absorber 610, a diluted, but still cool, desiccant fluid exits the absorber 610 as indicated at reference 622.

According to certain embodiments, dilute desiccant (e.g., a desiccant fluid) exits the absorber 610 to a pump 623. In certain operation, the absorber module can be operated in a batch configuration where a series of valves may be configured to isolate the absorber module from other portions of the AWG system, and to thereby recirculate the dilute desiccant along a recirculation flow path (while additional rich desiccant fluid is prevented from entering the closed loop via flow path 637 while appropriate valves remain closed) and through a pre-absorber heat exchanger 625 (e.g., a shell-and-tube heat exchanger, a plate heat exchanger, and/or the like) to cool the dilute desiccant (the opposite side of the heat exchanger is cooled water that has been collected from the overall system, as discussed in greater detail herein) before it is passed back into the top of the absorber 610 as indicated at 621. In this way, the amount of water absorbed into the desiccant fluid may be increased (thereby increasing the level of dilution of the desiccant) before the desiccant is directed to evaporation portions of the overall system.

In certain embodiments, the absorption module comprises a pre-absorber heat exchanger 625 that is cooled through the use of a chiller using a cooling media (e.g., water, glycol, and/or the like) that cools the rich desiccant flowing into the pre-absorber heat exchanger via flow path 624 (e.g., the cooling media is separated from the desiccant, such as on opposite sides of a heat exchanger) before the rich desiccant enters the absorber 610.

In certain operation, the absorber module can be operated in a continuous configuration where valves are configured to recirculate a certain amount of dilute desiccant fluid along the recirculation flow path and a certain amount of dilute desiccant fluid flows toward the water extraction module through a separate flow path (flow path 626) connecting the absorption module and the water extraction module. In this configuration, a certain amount of dilute desiccant fluid flows along the recirculation flow path through the pre-absorber heat exchanger 625 (e.g., a shell-and-tube heat exchanger, a plate heat exchanger, and/or the like) to cool the dilute desiccant fluid (the opposite side of the heat exchanger 625 is cooled using water that has been collected from the overall system) before it is passed back into the top of the absorber 610 as indicated at 621. Dilute desiccant fluid simultaneously traverses along a separate flow path 626 to the water extraction module. The cooling fluid passes through flow paths 661-667, which encompasses a recirculation loop of fluid, as well as a cooling system 662 and pump 664 that ensures adequate flow of fluid through the pre-absorber heat exchanger 625. Portions of the fluid return to a fluid store via flow path 667.

In certain embodiments, the absorber 610 is configured such that the rich desiccant is not cooled in a heat exchanger. In this embodiment, cooling of the desiccant fluid may be provided via thermal conductive heat exchange with ambient air through the conductive pipes along certain flow paths leading to an intake of the absorber. Fluid cooling may be provided in the absorber 610 as sensible heat is exchanged with the atmospheric air, provided that the air temperature is lower than the entering desiccant fluid temperature.

As just one example, rich desiccant fluid moving toward the absorber 610 may be directed through a series of geothermal tubes having heat transfer properties with surrounding ground beneath the AWG system. The rich desiccant fluid may directly pass through the series of geothermal tubes, or the rich desiccant fluid may pass through a dual-fluid heat exchanger opposite a cooling fluid that is maintained at a desired low temperature via geothermal cooling. As yet another example, the desiccant may pass through a heat exchanger (e.g., a shell-and-tube heat exchanger) to cool the desiccant fluid. The heat exchanger may be cooled via a cooling solution that passes through a refrigeration circuit and/or other fluid chiller to absorb heat from the desiccant fluid before the desiccant fluid enters the absorber 610.

As yet another example, the single-stage water consolidation system may be positioned proximate a high-pressure gas well, such as proximate a natural gas well, an oil well (where natural gas is extracted simultaneously with oil), and/or the like. The high pressure gas may be directed through one or more expansion valves to regulate and/or decrease the pressure of the incoming gas, which, through the Joules-Thompson effect, experiences a rapid temperature decrease (following the gas law formula, the pressure of the gas rapidly decreases across the valve while the volume and amount of gas remains substantially constant, thereby causing a proportional rapid temperature decrease across the expansion valve). The expanded and super-cooled gas may be passed through a heat exchanger opposite the rich desiccant fluid, thereby absorbing heat from the rich desiccant fluid and decreasing the temperature of the desiccant fluid prior to entry into the absorber 610. The expanded gas may then be directed away from the AWG system, where it may be collected for future use, flared off, utilized for power generation (e.g., via a steam turbine), and/or utilized to heat the desiccant fluid entering the water extraction module, as discussed herein.

In certain embodiments the absorber 610 is configured such that the diluted desiccant fluid exits the absorber 610 and is sent to the water extraction module without a recirculation path. Rich desiccant fluid returning from the water extraction module may or may not be cooled with a heat exchanger and/or chiller and/or geothermal cooling prior to entering the absorber 610. For example, dilute desiccant that exits the absorber 610 is pumped along a flow path extending between the absorption module and the water extraction module when appropriate valves are closed to prevent the dilute desiccant from recirculating into the absorber 610 as discussed above.

In certain embodiments, the absorber 610 may be embodied as a membrane-separated absorber, having a desiccant flow path on a first side of a porous membrane, and an air flow path on an opposite, second side of the porous membrane. Separating the air flow path from the desiccant solution flow path may impede undesirable mass flow of the desiccant salt (e.g., aqueous desiccant salt) itself into the air flow path and ultimately out of the AWG system. Water may be absorbed by the desiccant from the air based on osmotic water flow through the membrane from the air to the desiccant solution. Water vapor may condense on the second side of the membrane, travel through the membrane pores through capillary action, and be absorbed by the high-salt content concentrated desiccant solution. In certain embodiments, the membrane is embodied as a porous membrane, having pores of adequate size (e.g., average pore diameter, maximum pore diameter, and/or the like) to enable water molecules to pass through the membrane while the desiccant salt is prevented from passing through the membrane. As examples, the porous membrane may be a non-woven material, such as polytetrafluorethylene (PTFE), expanded polytetrafluorethylene (ePTFE), polypropylene (PP), polyvinylidene fluoride (PVDF), and/or the like. Other materials, including nylons and/or other synthetic materials may additionally be used in certain embodiments. In various embodiments, synthetic and/or natural materials may be utilized. The porous membrane may be at least partially woven in certain embodiments. In certain embodiments, the membrane may be organic, inorganic, polymeric, mesoporous, ceramic, and/or the like. In certain embodiments, the membrane may comprise metal organic frameworks, carbon nanotubes and/or a combination thereof. The membrane may be hydrophilic and/or hydrophobic or may be treated (e.g., with a coating) to allow the membrane to be hydrophilic and/or hydrophobic. As example membrane geometries, the membrane may be spiral wound, flat plate and frame style, or tubular. As the desiccant solution and the water flow past opposite sides of the membrane, water molecules migrate from the desiccant solution through the membrane (via capillary action), to the permeate water flow (e.g., water vapor and/or liquid water). In certain embodiments, the membrane may be supported within a frame via spacers, such as a lattice, a grid, and/or the like to provide mechanical support for the membrane to maintain a desired orientation of the membrane within the housing.

Various embodiments of the absorption module comprise a multi-stage absorber configuration, including a plurality of absorbers arranged in series (such that the desiccant flows from a first absorber, through a second absorber, and sequentially through additional absorbers within the multi-stage absorber configuration. Alternatively, the multi-stage absorber configuration encompasses a plurality of absorbers arranged in parallel, such that the desiccant is split to flow through the plurality of absorbers in parallel.

Moreover the plurality of absorbers may be arranged in series within the air flow path, such that source air may be pulled from the environment and passed through the plurality of absorbers in series prior to being exhausted back to the environment as dry air. For example, the source air may be first passed through the low concentration absorber to absorb a first quantity of water from the air, then may be passed through the high concentration absorber to absorb a second quantity of water from the air. Because the initial absorption requires less energy (and does not require a low vapor pressure between the air and the liquid desiccant), the initial absorption using the lower concentration desiccant fluid enables absorption of a first quantity of water from the air. After the initial, low energy requirement absorption process is completed, the air (which still contains water vapor) is passed through the second absorber having a higher concentration desiccant fluid, such that a second quantity of water is absorbed from the air. The now dry (e.g., low humidity) air may then be exhausted from the system to the environment.

On the desiccant side, once the dilute desiccant exits the low concentration absorber, the desiccant fluid passes to a water extraction module as discussed herein to extract water therefrom (and to consequently reconcentrate the desiccant).

In certain embodiments, each absorber may be in fluid communication with a corresponding water extraction module, such that each absorber is associated with a separate and independent desiccant flow path loop. For example, a first quantity of desiccant fluid may flow between a first absorber and a first water extraction module, and a second desiccant fluid may flow between a second absorber and a second water extraction module, and the first quantity of desiccant fluid does not mix with the second quantity of desiccant fluid. In certain embodiments, the first quantity of desiccant fluid may comprise a first desiccant (e.g., LiCl) and the second quantity of desiccant fluid may comprise a second desiccant (e.g., CaCl).

Moreover, in embodiments comprising a plurality of independent desiccant flows, each desiccant flow may have a different concentration range. For example, a first desiccant flow (e.g., corresponding to a first absorber passed through by source air) may have a first concentration range measured between a high concentration value at an exit of the water extraction module and a low concentration value at an exit of the absorber; and a second desiccant flow may have a second concentration range. As the source air is directed through the absorption columns in series, the air may be directed through a low concentration range absorption column first, and may be directed through a high concentration range absorption column second.

### Membrane-Based Water Extraction from a Desiccant

The water extraction module is provided to remove water from a diluted desiccant (e.g., from a diluted desiccant fluid) for storage and use as potable or other clean liquid water uses. The water extraction module comprises one or more membrane-based water extraction devices (e.g., connected in series or in parallel) and is connected to the absorption module via various flow paths to enable desiccant (e.g., diluted desiccant and rich desiccant) to flow between the absorption module and the water extraction module. The membrane-based water extraction device (also referred to as a fluid separation device) also acts to concentrate the desiccant solution into a concentrated desiccant retentate solution which may be reprocessed through the atmospheric water generation system.

The water extraction module comprises at least one membrane-based water extraction device 633 defining two flow paths separated by a permeable membrane 633a. On a first side of the permeable membrane 633a, the desiccant flows along a desiccant flow path (between flow path 632 and flow path 634) and on the opposite, second side of the permeable membrane, permeated fluid (e.g., water vapor) is captured then transferred (within portion 633c, located within the water extraction device between flow path 650 and flow path 651). Both the desiccant (on the first side 633b of the permeable membrane 633a) and the captured permeate fluid (on the second side 633c of the permeable membrane 633a) are in contact with opposite sides of the permeable membrane 633a while flowing past the permeable membrane 633a. The membrane 633a may thereby separate the desiccant flow path from the captured permeate (water vapor) flow path, which comprises water vapor collected during the water collection/fluid separation process (e.g., water vapor that migrates through the porous membrane 633a) and condenses into a liquid permeate water flow (e.g., downstream of the membrane-based water extraction device). In certain embodiments, mass transfer of water vapor across the membrane 633a may be driven by raising the vapor pressure of the desiccant. This may be accomplished by heating of the desiccant prior to contact with the membrane 633a (on the desiccant side 633b of the membrane). Lowering the pressure (e.g., by using a vacuum mechanism) to reduce the pressure on the permeate side 633c of the membrane 633a, also causes mass transfer of water vapor across the membrane. As the desiccant flows past the porous membrane 633a (on the first, desiccant side 633b of the membrane), the water in the desiccant begins permeation across the membrane 633a in the vapor state and exits the membrane 633a (on the second side) in the vapor state. The water vapor then condenses as it cools and flows along the water flow path (e.g., at least partially by utilizing a heat exchanger (e.g. condenser 627) and/or contacting it with a colder fluid (e.g. condensed water)).

In certain embodiments, the desiccant side 633b may be heated by a heating fluid (e.g., heating oil, steam, glycol, and/or the like) that is separated from the desiccant flow path within the membrane-based water extraction device via a heat-conductive layer (e.g., a heat-conductive, non-porous film, a metal sheet, and/or the like. In certain embodiments, the desiccant side 633b may be embodied as a shell-and-tube heat exchanger, with the heating fluid flowing through tubes and the desiccant flowing through the shell, with certain wall(s) of the shell being embodied as the porous membrane 633a. In certain embodiments, the heating fluid may be a product of the AWG system, thereby utilizing sensible heat transfer to heat the desiccant fluid to encourage water vapor migration across the membrane. In other embodiments, the heating fluid may be a product (e.g., a final product, a waste product, or an intermediate product) of a spatially proximate process, such as mining, gas extraction, power production, and/or the like.

As discussed in greater detail herein, the permeate side 633c may similarly comprise a heat-exchanger configuration to lower the temperature of the permeate fluid to encourage condensation thereof. For example, a cooling fluid (e.g., liquid water extracted from a liquid water storage tank 655, a refrigerant (e.g., glycol), and/or the like) may be separated from the permeate flow path by a heat-conductive layer (e.g., a heat-conductive, non-porous film, a metal sheet, and/or the like). The cooling fluid cools the heat-conductive layer, thereby providing a surface within the permeate fluid flow on which water vapor can condense. In certain embodiments, the permeate side 633c may be embodied as a shell-and-tube heat exchanger, with the cooling fluid flowing through tubes and the permeate fluid flowing through the shell, with certain wall(s) of the shell being embodied as the porous membrane 633a. In such embodiments, the outer surfaces of the tubes are provided as condensation surfaces for the water vapor. In certain embodiments, the cooling fluid may be a product of the AWG system (e.g., liquid water), thereby utilizing sensible heat transfer to cool the permeate to encourage water vapor migration across the membrane and to encourage condensation of the water vapor.

The membrane 633a may comprise a hydrophobic porous membrane, such as non-woven membrane having a small pore size. As just one example, the membrane may comprise PTFE, ePTFE, PP, PVDF, and/or the like, that is hydrophobic by design. In certain embodiments, the membrane may be organic, inorganic, polymeric, mesoporous, ceramic, and/or the like. In certain embodiments, the membrane may comprise metal organic frameworks, carbon nanotubes and/or a combination thereof, such as by stacking layers of material. The membrane may be hydrophilic or hydrophobic or may be treated (e.g., with a coating) to allow the membrane to be hydrophilic and/or hydrophobic. The use of a hydrophobic material (or a material having a hydrophobic coating) encourages water vapor to selectively pass through the membrane to be retained on the permeate water side 633c of the membrane. Adhering a layer of hydrophobic material to the membrane on the desiccant side 633b causes only volatile vapors to pass through and fluids in the liquid state are retained on the desiccant side 633b of the membrane. As examples of membrane geometries, the membrane may be spiral wound, flat plate and frame style, or a hollow tube. As the desiccant solution flows across the desiccant side 633b of the membrane, water molecules migrate from the desiccant solution through the membrane (via capillary action) in the form of vapor, to the permeated water side 633c, leaving a highly concentrated desiccant solution on the desiccant side 633b of the membrane 633a.

The membrane-based water extraction device 633 is embodied as a housing having a desiccant inlet and a desiccant outlet on the desiccant side 633b of the membrane 633a, and a permeate inlet and a permeate outlet on the permeate side 633c of the membrane 633a. In other example embodiments, the membrane-based water extraction device 633 may utilize gravity to remove permeate fluid from the membrane-based water extraction device 633, and in such embodiments, the permeate flow path need not include an inlet (such that gravity alone is sufficient to move the permeate fluid through an outlet of the device). For example, as the desiccant fluid flows from an inlet to an outlet of the membrane-based water extraction device, water vapor migrates through the membrane into vapor form on a permeate side of the membrane. The permeate side of the membrane may be cooled (e.g., using a cooling fluid separated from the permeate side of the membrane by a heat-conductive film), and water may condense within the permeate side of the membrane-based water extraction device and may fall (under the force of gravity) through an outlet port located on a bottom end of the permeate-side of the membrane.

The desiccant flow path extends between the desiccant inlet and the desiccant outlet. The permeate (water) flow path extends between the permeate inlet and the permeate outlet. In certain embodiments, the permeate outlet may be located below (and on an opposite end of the membrane-based water extraction device) the permeate inlet so as to utilize the force of gravity to encourage flow of permeate out of the membrane-based water extraction device. As mentioned above, each of the desiccant flow path and the permeate flow path interface the porous membrane 633a on opposite sides thereof. By separating the desiccant fluid from the permeate flow, the membrane 633a impedes mass transfer of dissolved solids from the desiccant into the resulting permeate flow, thereby preserving the desiccant for continuous usage and preserving the purity of the captured water. Similarly, the membrane impedes migration of a gas (e.g., a sweep gas) on the permeate side of the membrane 633a from permeating into the desiccant flow.

In certain embodiments, the housing defines two parallel flow paths that contact opposite sides of the porous membrane 633a in a counter-cross flow manner as illustrated in FIG. 2A, with the first flow path being the desiccant flow path 633b and the second flow path being the permeate flow path 633c, and the porous membrane 633a is embodied as a planar membrane (e.g., defined within a frame) that separates the desiccant flow path 633b from the permeate flow path 633c. In certain embodiments, the housing is configured to grant access to the porous membrane for maintenance purposes, such as to replace the membrane as needed. In other embodiments, a first flow (e.g., the desiccant flow) may flow in a horizontal direction across the surface of the membrane 633a) and a second flow (e.g., the permeate flow) may flow in a vertical direction across the opposite surface of the membrane, such as with the outlet of the permeate flow being below the inlet of the permeate flow.

In other embodiments, the desiccant flow path may be defined by a desiccant inlet that directs the desiccant toward the membrane (e.g., at a perpendicular angle or an at least substantially perpendicular angle relative to a first side of the membrane), and the desiccant is directed toward an outlet after the desiccant contacts the membrane. This embodiment is a dead end-style flow, where inlet desiccant interfaces the porous membrane in an at least substantially normal (perpendicular) direction of the permeate flow path on the opposite side of the membrane. In this embodiment, the permeate flow path flows parallel to the porous membrane. An example of this configuration is illustrated in FIG. 2B.

In yet other embodiments as illustrated in FIG. 2C, the housing may define a lumen-style flow path, with a first flow path being at least substantially concentric to a second flow path. Walls of the first flow path (separating the first and second flow path) may be at least partially defined by the porous membrane. In certain embodiments, the porous membrane may extend partially around the first flow path. In other embodiments, the porous membrane may extend around an entirety of the first flow path. As just one example, the first, interior flow path may be the desiccant flow path, and the second, outer flow path may be the permeate flow path, such that permeate water migrates through the porous membrane from the interior flow path to the exterior flow path. As another example, the first, interior flow path may be the permeate water flow path and the second, outer flow path may be the desiccant flow path, such that permeate water migrates through the porous membrane from the exterior flow path to the interior flow path.

In the lumen-style flow of the membrane-based water separation device, the permeate flow path and the desiccant flow paths may extend in the same co-current direction or in counter-current (opposite flow) directions. In certain embodiments, the flows may be horizontal, or vertical. In a vertical orientation, the permeate side may flow downward, thereby utilizing gravity to facilitate flow of the water (after condensation) out of the membrane-based water separation device.

To achieve separation of water from the desiccant solution, a difference in chemical potential is introduced. This may be realized in a temperature gradient across the membrane, a pressure gradient across the membrane, and/or a concentration gradient across the membrane between the desiccant flow path 633b, the membrane 633a, and the permeate flow path 633c. A temperature gradient across the membrane may be achieved by heating the desiccant fluid path 633b and/or cooling the permeate liquid water path 633c. The temperature of the desiccant fluid and/or the liquid water may be manipulated through the use of any heating/cooling source to include but is not limited to, heat exchangers, heating elements, waste heat, geothermal heat, solar heating, geothermal cooling, chilling, cooling pond, cooling stream, sweep gas, and/or the like. For example, the membrane-based water extraction device may incorporate a heat-exchanging configuration, such as across a non-porous film on a desiccant side of the membrane (e.g., a heating fluid may heat the desiccant fluid as it flows across a surface of the membrane) and/or a cooling configuration may be incorporated on the permeate side of the membrane (e.g., a cooling fluid separated from the permeate fluid across a non-porous film may cool the permeate fluid). A pressure gradient across the membrane may be achieved by high pressure on the desiccant side of the membrane and/or low pressure on the liquid water side of the membrane. The difference in pressure between the desiccant side of the membrane and permeate side of the membrane is not limited to but may be introduced by the following mechanisms, high pressure pumps, pumps, blowers, compressors, vacuum pumps, venturi vacuum induction mechanisms, and/or the like. Moreover, one or more pumps and/or agitators may be utilized on the desiccant side or the permeate water side to ensure homogeneity of properties of the desiccant and/or liquid water. Ultimately, the difference in pressure and/or temperature may provide a difference in vapor pressure on the two sides of the membrane so as to encourage water vapor to migrate through the membrane from the desiccant side of the membrane to the permeate/water-vapor side of the membrane. Specifically, the vapor pressure on the permeate side of the membrane may be lower than the vapor pressure on the desiccant-side of the membrane (e.g., to utilize an induced vacuum to drive permeation of the water through the membrane).

In certain embodiments, the membrane-based water extraction device is configured to utilize the mechanisms mentioned above to drive chemical potential. In one example incorporating vacuum membrane distillation (VMD), the permeate outlet path 651 is pressurized to a vacuum pressure (e.g., utilizing one or more vacuum pumps located downstream of the membrane-based water extraction device 633 along the permeate flow path, such as at compressor 652) to induce a pressure gradient across the membrane 633. As just one example, a vacuum pump may be located in the permeate water storage tank 655 and/or along flow path 659 of a gas vent from the water storage tank 655. In this embodiment, the absolute pressure on the desiccant side 633b is greater than the absolute pressure on the permeate side 633c. The interior of the membrane-based water extraction device may be analogous to that shown in FIGS. 2A-2C. In certain embodiments, additional components, such as a heating fluid flow and/or a cooling fluid flow (as discussed below) may additionally be incorporated into the VMD configuration of the membrane-based water extraction device to further enhance the efficiency of the water extraction process.

Another example embodiment utilizes air gap membrane distillation (AGMD) processes to drive permeation of water vapor across the membrane 633a to the permeate side 633c of the membrane 633a. Example AGMD configurations are shown in FIGS. 2D-2E, each of which provides for the permeate side of the membrane 633c to carry a cooling fluid along a cooling fluid flow path that is separated from the permeate flow path 633c by a heat-conductive, non-porous film (e.g., cooling water directed from storage tank 655, along flow path 658 to flow path 650 and into the membrane-based water extraction device 633 on the permeate side 633c of the membrane 633a). The cooling fluid flowing along flow path 633d sandwiches an air gap between a non-porous membrane 633e (separating the cooling fluid flow path 633d from the permeate side 633c of the membrane) and porous membrane 633a. The created air gap is formed with non-porous membranes 633e that promote condensing via heat transfer. The air gap serves as a path for condensates once they have separated from the desiccant via porous membrane. The cooling fluid is at a temperature below the heated desiccant fluid, thereby creating a temperature gradient starting from the heated desiccant side of the module 633b and finishing at the cool non-porous membrane holding the cooling fluid. The cool side also causes the transferred vapors to condense into a liquid state. A higher temperature gradient (a greater difference between the heated desiccant fluid and the cooling fluid) creates a greater driving force to separate water molecules within the concentrated desiccant across the porous membrane, thus achieving greater separation performance for the membrane-based water extraction device. As discussed above, the water vapor within the air gap may be directed out of the housing of the membrane-based water extraction device based on a vacuum created within the air gap, based on a sweep gas flowing through the air gap, and/or based on gravity that forces condensed water to flow downward and out through an outlet located at a bottom end of the air gap. In certain embodiments, the housing defines three outlets: a desiccant outlet (to flow path 634), a permeate outlet (to flow path 651), and a cooling fluid outlet (to recirculate cooling fluid along a cooling fluid flow path). In certain embodiments, the housing defines at least two inlets (when an inlet is not required for the permeate fluid, such as when gravity is utilized to direct the permeate fluid to exit the air gap) comprising a desiccant inlet (from flow path 632) and a cooling fluid inlet (e.g., from flow path 650). In other embodiments, the housing defines at least 3 inlets (when a permeate flow inlet is required, such as when utilizing a vacuum pressure or a sweep gas to direct the permeate out of the housing), comprising a desiccant fluid inlet (from flow path 632), a permeate fluid inlet (e.g., to enable a gas flow through the permeate side 633c of the membrane), and a cooling fluid inlet (e.g., from flow path 650).

Although illustrated as a flat-plane non-porous membrane 633d, it should be understood that the permeate side of the membrane 633a may be embodied as a shell-and-tube heat exchanger configuration (with the walls of the tubes embodying the non-porous film 633e and the cooling fluid flowing within the interior of the tubes).

Moreover, certain embodiments may provide an analogous configuration on the desiccant side of the membrane by utilizing a heating fluid separated from the desiccant by a non-porous, heat-conductive film, as shown in FIG. 2E. In such an embodiment, the heating fluid (e.g., a heating oil, steam, a heated refrigerant, and/or the like) passes along a flow path through heating fluid flow 633f, on an opposite side of the non-porous film 633g from the desiccant fluid 633b. The heating fluid transfers heat to the desiccant flowing through desiccant flow 633b, which encourages water vapor transmission across the porous membrane 633a. Particularly when the heating fluid flow 633f configuration is incorporated together with the cooling fluid flow 633d configuration, a large difference in chemical potential is introduced between the desiccant flow 633b and the permeate flow 633c to encourage migration of water across the membrane 633a. As discussed above, the water vapor within the air gap may be directed out of the housing of the membrane-based water extraction device based on a vacuum created within the air gap, based on a sweep gas flowing through the air gap, and/or based on gravity that forces condensed water to flow downward and out through an outlet located at a bottom end of the air gap. In certain embodiments, the housing defines three outlets: a desiccant outlet (to flow path 634), a permeate outlet (to flow path 651), a heating fluid outlet (e.g., to recirculate the heating fluid along a heating fluid flow path) and a cooling fluid outlet (to recirculate cooling fluid along a cooling fluid flow path). In certain embodiments, the housing defines at least three inlets (when an inlet is not required for the permeate fluid, such as when gravity is utilized to direct the permeate fluid to exit the air gap) comprising a desiccant inlet (from flow path 632), a heating fluid inlet, and a cooling fluid inlet (e.g., from flow path 650). In other embodiments, the housing defines at least four inlets (when a permeate flow inlet is required, such as when utilizing a vacuum pressure or a sweep gas to direct the permeate out of the housing), comprising a desiccant fluid inlet (from flow path 632), a permeate fluid inlet (e.g., to enable a gas flow through the permeate side 633c of the membrane), a heating fluid inlet, and a cooling fluid inlet (e.g., from flow path 650).

By separating the permeate flow 633c from the cooling fluid 633d as illustrated in either of FIGS. 2D-2E, the efficiency of permeation of water through the membrane may be increased due to a low vapor-pressure on the permeate side 633c of the membrane. A vacuum pressure, a sweep gas, and/or other flow-encouraging mechanisms may be implemented within the permeate flow 633c to encourage the water vapor on the permeate side 633c of the membrane to exit through the permeate outlet of the membrane-based water extraction device 633 and to be guided to one or more compressors (to incorporate beneficial features of mechanical vapor compression, similar to that described in co-pending U.S. Patent Appl. No. 17/552,173, filed on Dec. 15, 2021, the contents of which are incorporated herein by reference in their entirety). The water vapor exiting the permeate outlet of the membrane-based water extraction device may flow to one or more heat exchangers and/or one or more condensers 627 to condense the water vapor into liquid water before storing the same within storage tank 655.

Other embodiments implement direct contact membrane distillation (DCMD) processes to drive chemical potential across the membrane 633a. In a DCMD configuration, the permeate water side 633c of the membrane 633a carries a cooling fluid (e.g., cooling water) that directly contacts the porous membrane 633a. In such a configuration, water is directed from the storage tank 655 directly to the permeate flow 633c so as to maintain a low temperature on the permeate side 633c of the membrane 633a. Because the cooling fluid is at a lower temperature than the desiccant fluid, the cooling fluid creates a temperature gradient across the membrane 633a, starting from the heated desiccant side 633b and finishing at the direct contacting cooling fluid on the permeate side 633c of the membrane 633a. The cooling fluid may be retrieved from the storage tank 655 and directed into the membrane-based water extraction device 633 along flow paths 658 to 650 to 633c (and out of the membrane-based water extraction device at flow path 651). In certain embodiments, a portion of the water exiting the storage tank 655 along flow path 658 may be directed to external systems for use as liquid water. The permeate side 633c of the membrane 633a is fed by cooling fluid (e.g., liquid water from storage tank 655), which causes water vapors that have permeated through the membrane 633a to condense and transfer the water vapors separated from the concentrated desiccant. A higher temperature gradient (a greater difference between the heated desiccant fluid and the cooling fluid) creates a greater driving force to separate water molecules within the concentrated desiccant across the porous membrane, thus achieving greater separation performance for the membrane-based water extraction device.

As yet another example, a sweep gas membrane distillation (SGMD) process may be utilized to create a chemical across the membrane 633a. SGMD configurations may be combined with AGMD and/or DCMD to drive further efficiency of such configurations. According to an SGMD configuration, the permeate water side 633c of the membrane 633a carries a sweep gas (e.g., nitrogen gas, high-humidity air, inert gas, and/or the like) that transports permeated fluid (e.g., water vapor) away from the porous membrane 633a after it has permeated through the porous membrane. In certain embodiments, the sweep gas may carry the permeated water vapor to a compressor 652 and/or a condenser 627, where the water vapor condenses into liquid water. The sweep gas may be separated from the permeated water vapors by bringing the mixture to the water dew point and ultimately the sweep gas may be directed away from the liquid water along flow path 659, leading out of the storage tank 655. The sweep gas may be directed back to a storage tank, and it may be recycled into the system along flow path 660 as discussed above. Condensing the permeated water vapor into liquid enables the water to be stored in the product water tank 655. In certain embodiments, the SGMD configuration utilizes an inert gaseous state fluid as a sweep gas that does not contaminate the product water. In certain embodiments of SGMD, the flow of gas into the permeate flow path 633c is heated to retain the physical state of the permeated water (vapor state). To aid in maintaining the vapor state, heat tracing elements can be utilized to prevent the fluid pipe walls from cooling the fluid to liquid state. The water vapor may then be transported to a condenser 627 down stream from the membrane-based water extraction device 633 to condense the water, which is then stored within the water storage tank 655. Moreover, in the SGMD embodiments, the sweep gas may be introduced along flow path 660 and 650 into the membrane-based water extraction device. The sweep gas may be directed away from the liquid water after condensation by directing the sweep gas out of the water storage tank, such as along flow path 659 as shown in FIG. 1B.

In certain embodiments, the water extraction module comprises one or more heating mechanisms along a flow path leading the desiccant fluid into the intake of the membrane-based water extraction device (on the desiccant side 633b of the membrane 633a). In one example embodiment, the desiccant fluid is heated to a temperature between about 40-80° C. The process may result in adequate separation even at low temperatures (approximately 40° C.). In certain embodiments, the efficiency of separation may be increased at higher temperatures (e.g., between about 60-80° C.).

For example, diluted desiccant leaving the absorber module passes through one or more heating subsystems between the absorber module and the membrane-based water extraction device. These heating subsystems are provided as a part of the water extraction module. The one or more heating subsystems may comprise one or more of: a condenser 627, a pre-extraction heat exchanger 629, and/or a heater 631. It should be understood that the one or more heating subsystems may be provided in any order relative to the flow of desiccant. In one example, the diluted desiccant, which remains cool after passing through the absorber 610, passes through a condenser 627 which utilizes the generally cool temperature of the dilute desiccant to encourage condensation of water vapor from water vapor flowing along the permeate water flow path 651-654 (e.g., the water flow path encompassing the water flow path on the second side of the porous membrane). In certain embodiments, the condenser 627 is a shell-and-tube heat exchanger, with the dilute desiccant (upstream of the membrane-based water extraction device 633) passing through the tubes, and the water vapor condensing on the exterior of the tubes within the shell of the heat exchanger. In another embodiment, the condenser 627 is a plate-and-frame heat exchanger, with the dilute desiccant fluid passing through one set of plates and the water vapor passing through the other set of plates, and the water vapor condenses in the heat exchanger as it traverses through the heat exchanger as it warms the dilute desiccant. In another embodiment, the condenser 627 is a double-pipe heat exchanger where the dilute desiccant passes through the inner pipe and the water vapor passes through the outer pipe such that it can condense on the exterior surface of the inner pipe. In certain embodiments the condenser 627 may have a counter-flow configuration (the dilute desiccant flowing in an opposite direction than the water vapor). In other embodiments, the condenser 627 may have a parallel, co-current flow configuration in which the dilute desiccant and the water vapor flow in the same direction through the condenser 627.

The dilute desiccant exiting the condenser 627 via the flow path represented at 628 has an increased temperature due to a certain amount of heat transfer that is transferred from the water vapor to the dilute desiccant within the condenser 627. The dilute desiccant then passes through a pre-evaporator heat exchanger 629 (e.g., a shell-and-tube heat exchanger, a plate-and-frame heat exchanger, a dual-tube heat exchanger (with concentric tubes), and/or the like) and/or heater 631 (e.g., an externally powered heater, such as an electric heater, a natural gas heater, a solar heater and/or the like) to increase the temperature of the dilute desiccant to or near the evaporation temperature. In certain embodiments, the heater may be an inline electric heater with heating element bundles for heating the dilute desiccant fluid. The heater may have an orientation to reduce the likelihood of fluid flashing on the elements. The heater 631 may be positioned within the housing of the membrane-based water extraction device. In certain embodiments, the heater is a heat exchanger (e.g., a shell-and-tube heat exchanger, a plate-and-frame heat exchanger, and/or the like). In certain embodiments, the heater 631 is a solar heater utilizing photovoltaic panels to generate electrical energy to drive electrical heater elements (e.g., resistive heater elements). In certain embodiments, the heater 631 is a frenal lens heater utilizing solar energy to generate thermal energy in the form of heat. In certain embodiments, the heater 631 comprises a geothermal heater mechanism comprising a series of pipes extending into the ground to utilize geothermal energy to heat the dilute desiccant fluid. In other embodiments, the heater 631 is a fired heater utilizing a hydrocarbon fuel source (e.g., natural gas, oil, wood, biomass, and/or the like) combined with oxygen (supplied from ambient air) to create heat from combustion.

In embodiments comprising both a pre-extraction heat exchanger 629 and heater 631, the dilute desiccant fluid first exits the pre-extraction heat exchanger 629 via flow path represented at 630 before entering the heater 631. Moreover, as discussed in greater detail herein, the opposite side of the pre-extraction heat exchanger 629 is provided with heated rich desiccant fluid exiting the membrane-based water extraction device.

As the desiccant flows out of the heater 631 (if used), it flows along a flow path 632 into the housing, specifically into the desiccant inlet of the membrane-based water extraction device. In the membrane-based water extraction device, the desiccant solution is brought into direct contact with the membrane. Utilizing the difference in temperature, pressure, and/or concentration, the water migrates though the membrane and is collected on the second side. The water may migrate through the membrane as a liquid and/or as a vapor. The water may then be distributed for use and/or collected in a storage tank 655. In certain embodiments, the vapor on the liquid water side of the membrane may be collected in cool liquid water or another cool fluid to condense the vapor. The vapor on the liquid water side of the membrane may be swept away from the membrane using a sweep gas that flows through the membrane-based water extraction device on the liquid water side of the membrane. The vapor may then be condensed in a further process using a heat transfer process such as a heat exchanger or other embodiment of heat transfer process to condense the water vapor into liquid water (the opposite side of the heater exchanger and/or condenser may define a portion of a flow path of a chilled fluid, such as the dilute desiccant prior to entry into the desiccant side of the membrane-based water extraction device). In certain embodiments the vapor directly enters a heat transfer process on the permeate side of the membrane after exiting the membrane-based extraction device 633. The heat transfer process may be a heat exchanger 629 or other embodiment of heat transfer process to condense the water vapor into liquid water. In other embodiments, a vacuum may be induced on the permeate side of the membrane to achieve a difference in pressure between the desiccant side and permeate side of the membrane. The water enters the membrane as a liquid and/or vapor and exits the membrane on the permeate side as a vapor. The water flow path leads the water into a storage tank 655 (via flow paths 651-654, inclusive of pump(s), heat exchanger(s) 627, compressor(s) 652, and/or other flow-assisting devices. The water flow path also circulates from the storage tank via flow path 650 (inclusive of one or more pumps in certain embodiments, not shown) to the membrane-based water extraction device 633. In certain embodiments, a sweep gas (e.g., humid air) is blown through the water flow path (e.g., via a blower in-line with the water flow path) to push water vapor out of the membrane-based extraction device 633 into the compressor 652 and ultimately into the condenser 627.

In certain embodiments, the vapor on the permeate side is compressed through mechanical and/or thermal means to a higher pressure (e.g., via compressor 652). The vapor is then passed through a heat exchanger 627 to allow the latent heat to be used to heat the desiccant solution. Through this heat exchanger the vapor is also condensed as a liquid.

The membrane-based water extraction device 633 may be configured for batch operation, wherein the desiccant circulates within a closed loop to repeatedly contact the desiccant fluid with the membrane (without directing the desiccant to the absorption module) until a desired quantity of water has been separated. Valves within the water extraction module may be configured to provide the closed-loop flow of the desiccant solution. After the concentration of the desiccant solution reaches a desired level, the desiccant solution is then sent back to the absorption module by reconfiguring the valves to enable flow of desiccant from the water extraction module to the absorption module. The membrane-based water extraction device 633 may encompass a system of parallel subunits where multiple membranes are held in a single apparatus and/or multiple membrane-based water extraction devices are operated in parallel (with each device operating to separate water from a portion of the desiccant solution). In certain embodiments the membrane separation subunits may also be configured in a series configuration. In this configuration the desiccant solution is contacted with the first membrane and a certain amount of water migrates through the first membrane. The retentate desiccant solution from the first membrane is fed to a second membrane as the desiccant solution where an additional quantity of water is separated from the desiccant solution. The process is repeated for the number of membrane separation subunits in the series setup. In certain embodiments a combination of the parallel and series units may be utilized.

In certain embodiments the membrane-based water extraction device 633 is configured for continuous operation where a stream of desiccant is flowed in direct contact (e.g., perpendicular, parallel or tangential to the membrane face) with the membrane, and water is continuously separated from the desiccant solution via the membrane. The continuous mode operation may utilize series and/or parallel subunits as described in the section above. During continuous operation, the desiccant flows in a continuous loop from the absorption module to the water extraction module and back to the absorption module.

In certain embodiments, the membrane-based water extraction device may be provided in combination with an evaporation-based water extraction device (e.g., an evaporation vessel for evaporating water from the desiccant, and a condenser for condensing the evaporated water into potable liquid water). For example, the membrane-based water extraction device may be provided upstream (along the desiccant flow path) from an evaporation vessel such as an evaporation vessel as described in co-pending U.S. Patent Appl. No. 17/552,173, filed December 15, 2021 and co-pending Patent Appl. No. 17/690,550, filed March 9, 2022, the contents of which are incorporated herein by reference in their entirety. The membrane-based water extraction device may alternatively (or additionally) be positioned downstream (along the desiccant flow path) of an evaporation vessel as discussed above.

### Carbon Dioxide Capture using Metal-Organic Frameworks (MOFs) or Similar Techniques

Capturing CO₂ from combustion gases has become a major research area. Traditional post-combustion carbon capture often uses amine solvents, but these can be energy-intensive and suffer degradation. For example, advanced solid adsorbents like metal-organic frameworks (MOFs), which are porous crystalline materials composed of metal ions or clusters coordinated to organic ligands have been used. MOFs have exceptionally high surface areas and tunable pore sizes, allowing them to selectively adsorb gases like CO₂. Their modular nature enables customization of the framework structure and chemistry to optimize CO₂ capture performance. For example, a system using tetraamine-grafted MOFs to capture over 90–99% of CO₂ from flue gas, effectively enabling net-negative emissions. This illustrates how MOFs can be functionalized to selectively bind CO₂ even at low concentrations. Other disclosures propose MOF-based filters for vehicle exhaust or direct air capture, and some incorporate covalent organic frameworks or amine-functionalized sorbents as alternatives.

After CO₂ has been captured using metal-organic frameworks (MOFs) or similar techniques, the system may incorporate various methods for storing the captured CO₂. The captured CO₂ may be compressed and stored in high-pressure tanks or vessels.

These solutions, however, generally focus on the capture material and process itself (adsorbent composition, adsorption/desorption cycles) rather than integration with a particular facility’s operations. In a data center context, there is little precedent for combining on-site power generation with carbon capture. A new design incorporating MOF filters on a gas turbine exhaust must navigate around existing patents on MOF compositions and usage. The key will be emphasizing a unique system integration (using known MOF tech in a novel combined system), and possibly using specific MOF formulations not claimed by others. By doing so, the design can avoid infringing patents while still benefiting from MOF carbon capture capabilities.

### Air Conditioning via Gas Turbine Waste Heat

Data centers generate enormous heat and typically rely on power-hungry chillers or cooling towers. Combined cooling, heat, and power (CCHP) – also known as trigeneration – is a known strategy to improve efficiency. In trigeneration, an on-site gas turbine or engine produces electricity, and its hot exhaust (often ~500–600° C.) is repurposed to drive cooling systems. Systems where a gas turbine’s exhaust heats a boiler to produce steam for an absorption chiller or other refrigeration cycle.

Using gas turbines in data centers such that exhaust heat feeds a two-stage absorption chiller, yielding chilled water for server cooling and drastically reducing additional cooling water consumption. After the water is used for chilling servers, it exits the data center at an elevated temperature, and can be utilized to heat components of an AWG system.

These approaches demonstrate efficiency gains for cooling and power and may not include water recovery or carbon capture. Various embodiments use the exhaust heat for multiple purposes simultaneously (cooling and water extraction and CO₂ capture) in a coordinated way.

### Energy-Efficient Induced Airflow Mechanisms (Bernoulli’s Principle-Based Designs)

Passive or low-power airflow induction techniques can reduce the need for mechanical cooling. The Bernoulli principle (and related venturi or Coandă effects) is often exploited to amplify airflow: a high-velocity fluid stream creates a low-pressure region that draws in surrounding air. Designs include aspirator/jet pump devices that entrain ambient air into a primary airstream. For example, an airflow amplifier using a Venturi conduit: compressed air passes through a throat, entraining ambient air into the flow to augment total airflow output.

Similarly, bladeless fan technologies use shaped nozzles to pull additional air by entrainment. In building HVAC, static roof ventilators and windcatcher designs use wind (applying Bernoulli’s principle) to induce airflow for cooling without fans. These concepts show that induced airflow can improve ventilation/cooling efficiency. The innovation can be in how this principle is applied within the data center system – for instance, using the gas turbine’s exhaust stream as the motive flow in a custom-designed ejector to pull additional cool air through a heat exchanger. By tailoring the implementation to the unique layout (and perhaps using adjustable nozzles or controls), the design can benefit from airflow amplification.

### Post-Turbine Data Center Process Optimization

Operating on-site generators (like gas turbines or reciprocating engines) at data centers has been proposed to improve energy security and potentially sustainability. Beyond just producing electricity, optimizing post-turbine processes can greatly enhance overall efficiency. Strategies include: (1) Trigeneration for Data Centers – as noted, using waste heat for absorption cooling to reduce electrical chiller load. (2) Waste Heat Recovery for Water – outside of data centers, systems like vehicle exhaust AWG show waste heat turning into a water source, an idea that could be extended to stationary power units. (3) Flue Gas Treatment – power plant operators often implement emissions controls; in a data center context, one could similarly scrub or capture CO₂ from on-site generation. Certain data center focused configurations emphasize decarbonization, for example by fueling generators with green hydrogen to achieve near-zero carbon emissions. Certain embodiments target ultra-low Carbon Usage Effectiveness by using low-carbon hydrogen fuel for data center power. While effective, that approach requires new fuel infrastructure rather than capturing emissions. Various embodiments incorporate power, cooling, water, and emissions in a holistic system that combines these—power generation, cooling, water harvesting, and CO₂ scrubbing—surpassing the efficiency of any single approach.

Embodiments of the invention will now be described in detail, with reference to how each functional component interconnects to form an efficient data center resource system. It is understood that modifications can be made without departing from the spirit of the invention, and thus the scope is defined by the claims rather than this description.

### Overall System Architecture

Certain embodiments comprise a power plant including a gas turbine generator providing electric power to the data center’s servers via an electrical distribution panel. The turbine may be housed in an on-site energy center adjacent to the server room. Connected to the turbine’s high-temperature exhaust outlet is a heat recovery and distribution manifold that directs hot gases into two parallel paths: one leading to the cooling subsystem and another to the water extraction subsystem. Downstream of both, the flows recombine into a treated exhaust line that passes through the carbon capture unit before exiting to atmosphere via stack or being diverted to a storage tank (if CO₂ is liquefied).

All subsystems are monitored and controlled by a central control unit which interfaces with temperature sensors, humidity sensors, CO₂ sensors, flow meters, and motorized valves/dampers throughout the system. The control unit can adjust flow split in manifold, activation of pumps or fans, rotation speed of the desiccant wheel, and cycling of adsorption beds in unit to optimize performance.

### Absorption Cooling Subsystem

The cooling subsystem may be a double-effect absorption chiller in the preferred embodiment. It consists of a high-temperature generator, a low-temperature generator, a condenser, an evaporator, and an absorber, interconnected by fluid lines carrying a refrigerant (e.g., water/ammonia) and absorbent (e.g., lithium bromide solution) as is standard in absorption refrigeration. The hot exhaust gas from manifold enters the high-temperature generator, where it heats the absorbent-refrigerant solution to boil off refrigerant vapor. That vapor then passes to the low-temp generator which is heated by the still-hot gases (though slightly cooled) exiting the first generator (this cascading utilizes the exhaust heat twice for improved efficiency). After exchanging heat, the exhaust gas exits the chiller unit at a significantly reduced temperature (e.g., down from 600° C. to ~200° C.). Meanwhile, the refrigerant vapor condenses in condenser, releasing heat that is carried away by either an external cooling loop or the induced airflow mechanism described later. The condensed refrigerant goes through an expansion valve into evaporator, cooling the evaporator coils as it evaporates. These cold coils (filled with evaporating refrigerant) provide chilled water or air that is circulated to the data center racks via pump and fan units (not shown). The absorbent solution weak in refrigerant in absorber reabsorbs the refrigerant vapor coming from evaporator, aided by cooling water, completing the cycle. This absorption chiller thereby converts turbine waste heat into roughly 500 kW of cooling (for a mid-sized turbine) to maintain safe temperatures in the server room.

Notably, the integration point to the rest of the system is at the exhaust interface: the heat recovery manifold directs perhaps 70% of the turbine exhaust mass flow through the absorption chiller generators. Valves controlled by unit regulate this percentage based on cooling demand. If cooling demand is low (e.g., on a cool day or partial IT load), more exhaust can be bypassed directly to the water extractor or a bypass stack. Conversely, on a high IT load day, the chiller may take the majority of exhaust heat. The spent exhaust gas from the chiller, now at ~200° C. and carrying water vapor (from the absorber cooling spray), flows into a mixing plenum where it meets the other stream from the water subsystem (if any), then goes into the carbon capture unit.

### Water Extraction Subsystem

In some embodiments, the water extractor (e.g., AWG system) uses a rotary desiccant dehumidifier coupled with a regenerative heating section. Other embodiments may utilize the AWG system described above. The subsystem includes an intake duct drawing in ambient air, a desiccant wheel, a regeneration chamber, a condenser, and a water collection reservoir. The desiccant wheel is a circular matrix (for example, a silica gel or MOF-infused composite structure) that slowly rotates (driven by motor) such that each segment of the wheel periodically passes through the process air stream (ambient intake) and then the reactivation air stream (heated exhaust).

Operation is as follows: Ambient air (which might be warm and humid, e.g., 30° C., 60% RH) is pulled through the process side of wheel by a fan. As the air passes, the desiccant material adsorbs moisture, drying the air. This dry air (now perhaps 30° C., 10% RH) is routed either into the data center for additional cooling benefit (since dehumidified air can absorb more heat from servers), or simply vented out if not needed. As the wheel rotates, that moisture-laden section moves into the regeneration chamber. Here, a portion of the turbine’s exhaust is directed by manifold into a heat exchanger that heats air in the regeneration chamber to a high temperature (e.g., 120–150° C.) to drive off the water from the desiccant. In one design, the regeneration air is actually a split of the exhaust gas itself (this could be viable if the exhaust is kept separate and non-contaminating, or if a heat exchanger isolates clean air from the actual exhaust stream). The released water vapor is then condensed on condenser coils which are cooled by either ambient air or a coolant loop from the absorption chiller’s condenser, achieving further heat integration. The result is liquid water that drips into the collection reservoir. Any remaining reactivation air (now cooled and moisture-depleted) is then mixed back with the main exhaust flow in plenum before carbon capture.

This subsystem effectively produces fresh water. The design incorporates a distinctive configuration: utilizing the exhaust stream for dual purposes (first cooling, then regeneration) and positioning the dehumidifier within a data center's air cycle.

Additionally, the desiccant wheel can be of a novel composition (for instance, a MOF coating that enhances water uptake at higher humidity, different from standard silica gel wheels) – such composition can itself be a dependent claim if it provides performance advantages.

Alternate embodiments might replace the wheel with a liquid desiccant system: e.g., a packed bed absorber where ambient air bubbles through a cool hygroscopic solution (like lithium chloride brine) to absorb moisture, and a separate reboiler heated by exhaust to evaporate water from the brine. Both approaches share the common inventive integration of using turbine waste heat for water. The condensed water in reservoir can be piped to storage tanks (not shown) for treatment and use. The control unit ensures that regeneration heating is supplied at the right rate – if the data center requires more cooling than water, the system can temporarily slow the wheel to adsorb more moisture (storing it in the desiccant) and prioritize chiller heat usage, then later speed up to catch up on regeneration when cooling load dips.

### Carbon Capture Subsystem

The carbon capture unit is positioned after both useful outputs (cooling and water) have been extracted from the exhaust, thereby treating the combined exhaust stream. By this point, the gas entering unit is relatively cool (around 40–60° C.) and near ambient pressure, containing primarily N₂, O₂, CO₂ (~4–5% if natural gas fuel), and residual humidity. The subsystem comprises an array of adsorption columns filled with a CO₂-selective adsorbent. We describe it in terms of MOF beds for specificity: each column is packed with pellets of a metal-organic framework material that has a high affinity for CO₂ but low affinity for N₂/O₂. For example, Mg₂ MOF modified with tethered diamines (a known high-performing direct air capture sorbent) could be used, or any suitable equivalent. The exhaust gas is blown through one of the columns in an adsorption phase. The MOF captures CO₂ molecules, and purified nitrogen-rich gas exits to the atmosphere from vent. After some time or once the outlet CO₂ level starts rising (indicating saturation), the control switches the flow to a second column and initiates regeneration of the first. Regeneration is achieved by either heating the bed (using a built-in heating element that may be electric or utilize a small bleed of hot exhaust if available) and/or drawing a vacuum via vacuum pump. In this design, we assume temperature swing adsorption (TSA) for simplicity: the bed is heated to ~120° C. to release CO₂. The desorbed high-purity CO₂ is collected in a header line and cooled/compressed by compressor into a storage tank or prepared for further utilization (like feeding a greenhouse or carbonating a liquid, not shown). Once regenerated, the column cools (perhaps accelerated by a fan or purge cycle) and stands by for the next adsorption cycle.

This two-bed system ensures continuous capture. More columns can be added in parallel for larger systems. The control algorithm times the heating such that it might occur when the turbine load is steady and the absorption chiller doesn’t need peak heat. Optionally, if the data center has periods of low load at night, the system can run in a load-following mode: adsorbing CO₂ all day while the turbine is on, then regenerating all columns at night using stored heat or a small electric heater when power demand is low. This flexibility in operation is a key advantage of integrating on-site – the system operator can balance priorities between cooling, water, and CO₂ capture dynamically.

To prevent any performance interference, there are filters to remove any particulate or NOx/SOx from the exhaust before it contacts the MOF, which protects the sorbent’s longevity (though a well-tuned turbine on clean fuel emits very low NOx that can be manageable). In scenarios where the CO₂ purity is not critical (e.g., venting captured CO₂ into a local algae farm), the system could even alternate between directing exhaust to the MOF unit or bypassing it to modulate how much CO₂ is captured.

In certain embodiments the CO₂ capture MOF may also be in a wheel format to allow for continuous capture on a single piece of equipment. In this case the CO₂ rich air would enter on side of the rotating wheel while air that was heated using the exhaust gas causes desorption on another section of the rotating wheel.

### Induced Airflow Mechanism and Data Hall Integration

An important innovation is the use of the turbine’s own outputs to facilitate airflow. A venturi ejector is installed at the junction of the exhaust manifold and the absorption chiller’s exhaust outlet. This ejector has a narrowed throat where the high-speed exhaust flow from the turbine creates suction. An inlet port on the ejector draws in ambient air (or potentially hot air from the data center ceiling plenum) and entrains it into the exhaust stream. The mixed air then enters the absorption chiller’s condenser section to carry away heat, or directly goes to the stack after mixing with exhaust, depending on configuration. In one embodiment, the ejector pulls air through a set of heat exchanger coils that precool the intake air using cool water from the chiller’s output, effectively creating a rudimentary cooling tower powered by the exhaust flow. This increases the chiller efficiency by rejecting heat without electric fans. Additionally, separate smaller venturi devices can be placed in the data center’s hot aisle exhausts – using either the building’s exhaust or small compressed air streams – to suck hot air out of racks more efficiently.

The Bernoulli principle thus finds two uses here: improving the chiller heat rejection and potentially ventilating the server room. The design ensures these ejectors are tuned to the turbine’s operating range (valve can adjust the motive flow or a movable nozzle can optimize suction). Because these are integrated with the waste heat path, they essentially provide free cooling augmentation whenever the turbine is running at sufficient load.

### Control System and Optimization

The central control unit is programmed with an optimization routine that takes into account the data center’s real-time Power Usage Effectiveness (PUE) and Water Usage Effectiveness (WUE), as well as Carbon Usage Effectiveness (CUE) targets. The control strategy might involve the following:

Heat Distribution Control: A PID-controlled damper in the exhaust manifold splits flow between the chiller and the regenerator. If server temperatures begin to rise, the controller biases more heat to the chiller to boost cooling. If server temperatures are stable and the humidity sensor indicates the desiccant is saturated (rise in humidity downstream of wheel), the controller sends more heat to regenerate the desiccant and gather water. During periods of very low cooling demand (e.g., cool night), the controller can even divert all exhaust to a bypass to avoid overcooling, and instead use a small auxiliary heater to regenerate desiccant if water is needed, or just idle until needed again. This smart allocation ensures no waste heat goes unused unless absolutely necessary.

In some aspects, artificial intelligence (AI) techniques may be employed to enhance and optimize the control system operation. Machine learning algorithms, such as reinforcement learning or neural networks, may be utilized to continuously improve the system's performance over time. These AI models may analyze historical data on system behavior, environmental conditions, and data center load patterns to predict future demands and optimize resource allocation.

The AI-driven control system may adapt its decision-making processes based on real-time data inputs, potentially leading to more efficient heat distribution, water production, and carbon capture. For example, the system may learn to anticipate cooling needs based on weather forecasts and scheduled workloads, preemptively adjusting the absorption chiller output or desiccant wheel rotation speed.

In some implementations, the AI may optimize the trade-offs between different subsystems, balancing cooling efficiency, water production, and carbon capture based on current priorities and conditions. The system may also identify and suggest potential improvements in overall system configuration or operation, such as adjusting flow rates or regeneration cycles for optimal performance.

Additionally, AI algorithms may be used for predictive maintenance, analyzing sensor data to detect potential issues before they lead to system failures or inefficiencies. This proactive approach may help maintain high system availability and performance over time.

Water-Cooling Tradeoff: The system can intentionally overcool the data center air to condense some water directly via HVAC if needed or use the desiccant system more heavily when external water supply is low. These modes are software-selectable. For instance, an “eco mode” might maximize water harvesting (for highest self-sufficiency) by occasionally reducing chiller usage (letting server inlet temp go a bit higher but still safe) to free up heat for the desiccant regenerator.

CO₂ Capture Management: The control unit schedules regeneration of CO₂ adsorbers when it will least impact other operations. If using TSA (thermal swing), it might slightly increase fuel burn or divert heat for a short period to heat the beds – this could be done when cooling load is lower (morning or evening). If using pressure swing, it will activate the vacuum pump in cycles that align with power availability. The goal is to capture >90% of CO₂ over a daily cycle without causing noticeable efficiency loss to cooling or power. The controller can also decide to vent exhaust (bypass carbon capture) under certain conditions (e.g., emergency full power mode), to ensure reliability of the data center – such bypass events can be logged for later offsetting if needed.

Safety and Redundancy: The integrated system has interlocks such that if one part fails (say the chiller needs maintenance), the manifold can redirect exhaust away from it and the data center can fall back to traditional cooling (there might be backup electric chillers or CRAC units for redundancy). Similarly, if the CO₂ unit is offline, exhaust simply goes out the stack. The water system can be isolated if not needed. These contingencies ensure the data center can always operate – albeit at lower efficiency – even if the integrated system has downtime. This practical aspect makes the design feasible in real-world deployment.

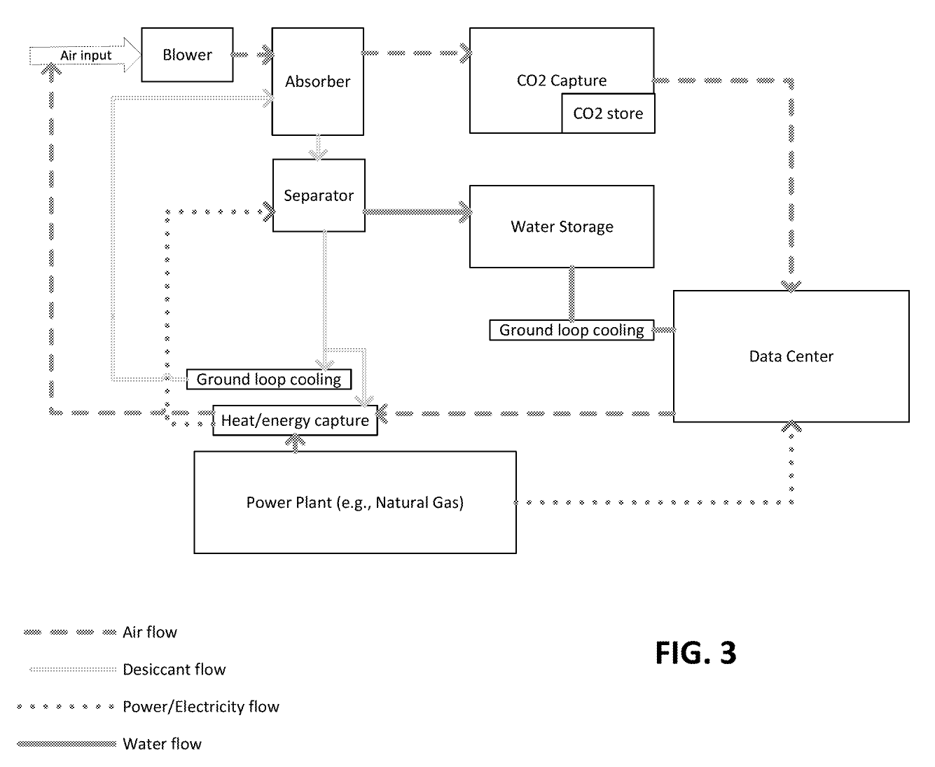

FIG. 3 illustrates a system diagram of an atmospheric water generation system integrated with a data center and power plant. The diagram depicts multiple interconnected components and subsystems, with various types of flow paths indicated by color-coded lines. Green dashed lines represent air flow, yellow double lines show desiccant flow, red dotted lines indicate power/electricity flow, and blue solid lines denote water flow.

The system receives input feeding into a blower, which directs air into an absorber unit. This absorber is connected to both a CO2 capture system (which includes a CO2 store) and a separator unit. The separator links to a water storage component, which incorporates ground loop cooling.

In some aspects, the blower may be optional if the air is input to the system at high velocity. For example, when the air input is sourced from the exhaust of a natural gas power plant turbine, the exhaust gases may already possess sufficient kinetic energy to flow through the system without additional propulsion. The high-velocity exhaust from the turbine may provide adequate momentum to drive the air through the absorber unit and subsequent components. In such cases, the system may leverage the inherent energy of the exhaust stream, potentially reducing the need for separate blower equipment and associated energy consumption. However, the inclusion of a blower may still be beneficial in certain configurations or operating conditions to ensure consistent airflow and system performance across varying input velocities.

The absorber unit may be embodied as a vessel designed to bring ambient air into contact with a desiccant solution. In some aspects, the absorber may receive ambient air through an inlet positioned near the bottom of the vessel. The air may then flow upward through the absorber, exiting as dry air near the top.

Concurrently, a desiccant solution may enter the absorber through an inlet proximate to the top of the vessel. The desiccant may flow downward through the absorber due to gravity, contacting the rising air stream. This counter-flow configuration may allow for efficient moisture transfer from the air to the desiccant.

As the desiccant absorbs moisture from the air, it becomes diluted. The diluted desiccant may exit the absorber through an outlet (e.g., positioned near the bottom of the vessel). In some cases, this diluted desiccant may be directed to other system components for regeneration or further processing.

The separator unit may function to separate water from the desiccant solution after it has absorbed moisture from the air in the absorber. In some implementations, the separator may utilize a membrane-based extraction device, where a porous membrane separates a desiccant chamber from a permeate chamber. The desiccant solution may flow through the desiccant chamber, while water vapor permeates through the membrane into the permeate chamber. Heat may be applied to the desiccant solution to increase its vapor pressure and facilitate water extraction. The extracted water vapor may then be condensed and collected for various uses within the data center or other applications.

The concentrated desiccant leaving the separator may be at an elevated temperature due to the heat applied during the separation process. This hot concentrated desiccant may be utilized in various ways to improve overall system efficiency. In some aspects, the hot desiccant may be used to power low-grade heat engines or thermoelectric generators, potentially providing supplemental electricity for auxiliary systems. Additionally, the hot concentrated desiccant may be directed through a heat exchanger to pre-heat the incoming dilute desiccant before it enters the separator. This heat recovery process may reduce the overall energy required for water separation. After transferring some of its heat, the concentrated desiccant may be further cooled using a geothermal cooling system. In some implementations, the desiccant may flow through a series of underground pipes or a ground-coupled heat exchanger to lower its temperature before being directed back to the absorber. This geothermal cooling approach may help maintain optimal absorption conditions in the absorber while utilizing renewable ground-source cooling.

The absorber may be designed to operate in various flow configurations. While a counter-flow arrangement may be common, cross-flow or other configurations may also be implemented depending on specific system requirements or design constraints.

The CO2 capture system may include multiple adsorption columns filled with a CO2-selective adsorbent, such as a metal-organic framework (MOF) material. These columns may operate in alternating cycles, with one column actively adsorbing CO2 from the exhaust gas while another undergoes regeneration.

The exhaust gas from the power plant, after passing through the absorption cooling and water extraction subsystems, may be directed to the CO2 capture system. As the exhaust gas flows through an active adsorption column, the MOF material may selectively capture CO2 molecules, allowing other gases to pass through. The purified, nitrogen-rich gas may then be vented to the atmosphere.

When an adsorption column approaches saturation, as indicated by rising CO2 levels at the outlet, the system may switch the gas flow to a fresh column. The saturated column may then enter a regeneration phase, which may involve heating the bed to around 120° C. using built-in heating elements or a portion of the hot exhaust gas. This temperature swing may cause the release of high-purity CO2, which may be collected, cooled, and compressed for storage or further use.

The CO2 capture system may be designed for continuous operation, with multiple columns operating in parallel to ensure uninterrupted CO2 removal. The control system may optimize the timing of column regeneration based on factors such as turbine load, cooling demand, and power availability. This integration may allow for flexible operation, potentially including load-following modes where CO2 is captured during high-load periods and regeneration occurs during off-peak hours.

In some configurations, the CO2 capture system may incorporate a rotating wheel format, where CO2-rich air enters one section of the wheel while heated air causes desorption in another section, enabling continuous capture on a single piece of equipment.

The captured CO2 may be stored in a dedicated CO2 store, as shown in the diagram. This stored CO2 could potentially be used for various applications, such as feeding greenhouses, carbonating liquids, or supporting algae cultivation, depending on the specific implementation and local needs.

A data center is depicted at the bottom right of the diagram, receiving water input from the water storage (after cooling) and receiving air input from the CO2 capture system (after cooling and dehumidification). A power plant, specified as potentially using natural gas, is shown at the bottom left. Moreover, the power for the data center (e.g., for servers, lights, cooling systems, and/or the like) may be provided by a power plant (e.g., a natural gas power plant) that is sized for the system alone.

The water extracted from the atmospheric water generation system may flow through a ground loop cooling system before entering the data center. In some implementations, this ground loop cooling system may utilize geothermal principles to further cool the water. The ground loop may consist of a network of pipes buried at a depth where the earth's temperature remains relatively constant throughout the year. As the water circulates through these underground pipes, it may exchange heat with the surrounding soil, potentially lowering its temperature.

This geothermally cooled water may then be directed into the data center's cooling infrastructure. The use of a ground loop cooling system may provide several benefits. It may reduce the energy required for additional mechanical cooling, as the earth acts as a natural heat sink. This approach may also help stabilize water temperatures, potentially improving the efficiency and consistency of the data center's cooling processes.

In some cases, the ground loop cooling system may be designed with multiple stages or zones, allowing for fine-tuned temperature control. The system may also incorporate sensors and control valves to optimize flow rates and maximize heat transfer based on current conditions and cooling demands.

The water input from the atmospheric water generation system may be utilized in a water-cooling system for servers in the data center. In some aspects, the extracted water can be directed to a cooling loop that circulates through the server racks. This cooling loop may consist of a network of pipes or tubes that come into thermal contact with heat-generating components within the servers.

The water may first pass through a heat exchanger to lower its temperature, potentially utilizing the absorption chiller's output or ground loop cooling. Once cooled, the water can be pumped through the server cooling system, absorbing heat as it flows past processors, memory modules, and other heat-generating electronics.

In some implementations, the water cooling system may incorporate cold plates directly attached to high-heat components like CPUs and GPUs. These cold plates may allow for efficient heat transfer from the components to the circulating water. The warmed water exiting the server racks can then be routed back through the cooling system to reject the absorbed heat and continue the cycle, or it can be added back to the water storage device.

The water-cooling system may also integrate with the data center's broader thermal management strategy. For instance, in some cases, the water can be used in cooling towers or evaporative cooling systems to help maintain optimal environmental conditions within the data center. This integration may allow for dynamic allocation of cooling resources based on real-time server loads and environmental conditions. Any water that evaporates as a part of the data center cooling may be captured in a controlled air stream (e.g., the exhaust air of the data center and/or data center cooling system), which may be redirected to the air input of the AWG system discussed herein.

Additionally, the water cooling system may incorporate sensors and control valves to monitor and adjust flow rates and temperatures throughout the cooling loop. This level of control may enable fine-tuning of cooling performance to match the specific thermal needs of different server configurations or workloads.

In some implementations, the exhaust air exiting the CO2 capture system may be utilized as input air for the data center's air cooling system. This approach may offer several potential benefits to the overall system efficiency.

The exhaust air, after passing through the CO2 capture system, may have a lower temperature compared to ambient air. This cooler air may be directed into the data center's air handling units or directly into the server rooms, potentially reducing the energy required for cooling. By leveraging this pre-cooled air, the data center may decrease the load on its primary cooling systems, which may lead to improved energy efficiency and reduced operational costs.

In some cases, the system may incorporate heat exchangers or mixing chambers to blend the cool exhaust air with fresh ambient air before it enters the data center. This blending process may allow for precise control of the input air temperature and humidity levels, potentially optimizing the cooling performance while maintaining appropriate air quality standards for the data center environment.

The integration of the CO2 capture system's exhaust air into the data center cooling infrastructure may be managed by the central control system. Sensors may monitor the temperature, humidity, and other relevant parameters of the exhaust air, allowing the control system to dynamically adjust the proportion of exhaust air used for cooling based on current conditions and cooling demands.

In some implementations, the system may include bypass ducts or dampers to regulate the flow of exhaust air into the data center cooling system. These components may allow for flexible operation, enabling the system to utilize the cool exhaust air when beneficial while maintaining the ability to switch to conventional cooling methods if needed.

By repurposing the cool exhaust air from the CO2 capture system, the integrated system may achieve additional synergies between its subsystems, potentially enhancing overall efficiency and resource utilization. This approach may contribute to the data center's efforts to reduce its environmental impact and operational costs associated with cooling.

A natural gas power plant may utilize a gas turbine generator to produce electricity. In some configurations, the gas turbine consists of a compressor, combustion chamber, and turbine. The compressor draws in ambient air and pressurizes it before it enters the combustion chamber. Natural gas is then injected into the combustion chamber and ignited, creating hot, high-pressure gases. These gases expand rapidly through the turbine, causing it to spin at high speeds. The turbine is connected to a generator, which converts the mechanical energy of the spinning turbine into electrical energy.

The efficiency of a natural gas power plant may be enhanced through the use of combined cycle systems. In such systems, the hot exhaust gases from the gas turbine, which still contain a significant amount of thermal energy, are directed to a heat recovery steam generator (HRSG). The HRSG uses this waste heat to produce steam, which can then drive a steam turbine to generate additional electricity. This configuration may allow for overall plant efficiencies of up to 60% in some cases, significantly higher than traditional single-cycle gas turbine plants. Additionally, the flexibility and rapid start-up capabilities of gas turbine generators may make them well-suited for meeting fluctuating power demands and supporting grid stability.

The diagram demonstrates multiple ground loop cooling connections throughout the system. Various interconnected flows between components create a closed-loop system where resources such as air, water, and CO2 are processed and utilized across multiple processes.

The layout effectively shows how exhaust air from the data center may be directed as input to the absorber unit of the atmospheric water generation system. It also illustrates how waste heat from the power plant may be captured and utilized within the integrated system.

This integrated approach allows for efficient use of resources, with the atmospheric water generation system providing water for the data center, while also capturing and potentially utilizing CO2. The system's design enables heat recovery from both the power plant and data center operations, contributing to overall system efficiency.

### Alternative Embodiments and Variations

While the described embodiment uses a gas turbine, the inventive concept could apply similarly to other on-site generation sources like reciprocating gas engines, fuel cells with high temperature output, or even industrial waste heat streams co-located with a data center. For example, a large diesel generator’s exhaust (which is also hot) could feed a slightly modified system; one difference might be managing the soot in diesel exhaust before it hits the desiccant or MOF. In another variant, a solid oxide fuel cell running on natural gas outputs hot exhaust ~300° C.; although lower temperature than a turbine, it is still viable to drive a single-effect absorption chiller and a desiccant regenerator. The principles of cascading energy remain the same.

The components can also be varied: Instead of an absorption chiller, certain embodiments could use an adsorption chiller (using solid sorbents like silica gel beds cooled by water) which might integrate even more neatly with the desiccant water system (potentially using the same material in dual roles). Chilling of the air and or process streams of a liquid desiccant process may also use geothermal cooling. The water harvesting could alternatively use direct condensation if humidity and conditions permit – for instance, using the cold output of the chiller to condense water from air (this is essentially a dehumidification coil approach rather than desiccant). However, desiccant methods are advantageous in hot-dry climates where direct condensation is inefficient, so the design presented is optimized for those conditions.

Likewise, carbon capture might be accomplished with alternative chemistries: amine scrubbers (a liquid process) could be used if one is willing to handle the chemical logistics; however, MOFs or solid sorbents are more modular and easier to fit in a container on-site. We could also envision direct air capture integration, where not just the turbine exhaust but ambient air is drawn through CO₂ sorbents during off-peak times, potentially capturing even more CO₂ from the environment (making the data center a carbon-negative hub). This would, of course, require additional heat or energy to regenerate sorbents for ambient CO₂, but the system’s efficiencies might allow it if surplus energy exists.

In terms of physical layout, the subsystems could be co-located in a single mechanical hall or distributed. One could mount the water extractor on the roof (exposed to ambient air flow) with ducts carrying exhaust heat to it, while the chiller sits in a plant room and the CO₂ unit outside. The ejector and induced airflow features might be built into the exhaust flue design or the cooling tower structure. These design choices can be adapted to specific site constraints.

Overall, any embodiment that uses the cascade of energy from high-grade to low-grade to accomplish multiple resource outputs (cooling, water, and emissions reduction) should be considered within the scope of this invention. The detailed description above provides a template for implementation, and it is understood that equivalent substitutions (of materials, fluids, or sequence) that achieve the same functional result are intended to be covered. For instance, if a future material arises that adsorbs both water and CO₂, one could envision a single unit that does both – our system architecture could accommodate that by splitting flow appropriately. Such variations underscore the flexibility and robustness of the inventive concept.

A number of implementations have been described. Nevertheless, it will be understood that various modifications may be made without departing from the spirit and scope of the disclosure. Accordingly, other implementations are within the scope of the following claims.

What is claimed is:

1. An integrated data center resource system, comprising:
a gas-fired generator configured to supply electrical power to a data center and produce a hot exhaust stream;
an absorption cooling subsystem thermally coupled to the hot exhaust stream and configured to produce chilled coolant for cooling data center equipment;
a desiccant-based water harvesting subsystem receiving at least a portion of the hot exhaust stream to regenerate a moisture-absorbing desiccant, the desiccant-based water harvesting subsystem arranged to extract water vapor from ambient air and to release and condense liquid water when heated by the hot exhaust stream;
a carbon capture subsystem downstream of the absorption cooling subsystem and the desiccant-based water harvesting subsystem, comprising a CO₂-selective sorbent material through which cooled exhaust gas is passed to remove carbon dioxide; and
a control system operatively connected to the absorption cooling subsystem, desiccant-based water harvesting subsystem, and carbon capture subsystem, wherein the control system dynamically allocates the hot exhaust stream among the absorption cooling subsystem, desiccant-based water harvesting subsystem, and carbon capture subsystem to simultaneously provide cooling to the data center, recover water, and reduce carbon emissions.

2. The integrated data center resource system of claim 1, wherein the desiccant-based water harvesting subsystem includes a rotating desiccant wheel that continuously alternates between an adsorption zone exposed to incoming ambient air to pick up moisture and a regeneration zone exposed to a heated air stream from the hot exhaust stream to release moisture, and a condenser that converts the moisture released into liquid water for collection.

3. The integrated data center resource system of claim 2, wherein the regeneration zone is heated by a heat exchanger transferring thermal energy from the hot exhaust stream to a flow of air that passes through the rotating desiccant wheel, such that the hot exhaust stream does not directly contact the moisture-absorbing desiccant.

4. The integrated data center resource system of claim 1, wherein the desiccant-based water harvesting subsystem uses a liquid desiccant solution contained in an absorber and a regenerator, such that ambient air is dehumidified by contact with the liquid desiccant solution in the absorber and a portion of the hot exhaust stream heats the liquid desiccant solution in the regenerator to evaporate and recover water.

5. The integrated data center resource system of claim 1, wherein the absorption cooling subsystem is a double-effect absorption chiller that receives the hot exhaust stream in a high-temperature generator and a medium-temperature generator in series, thereby extracting multiple stages of cooling from the hot exhaust stream and outputting a reduced-temperature exhaust stream to the carbon capture subsystem.

6. The integrated data center resource system of claim 5, wherein the absorption cooling subsystem is configured to produce chilled water or chilled air delivered to an air conditioning system of the data center, and further includes controls to modulate cooling output by adjusting exhaust gas flow through the absorption cooling subsystem in response to data center equipment temperature or load.

7. The integrated data center resource system of claim 1, wherein the carbon capture subsystem comprises at least one metal-organic framework (MOF) sorbent arranged in one or more reaction chambers, and a regeneration system for regenerating the MOF sorbent to release captured CO₂, such that greater than 90% of CO₂ in the cooled exhaust gas can be removed during normal operation.

8. The integrated data center resource system of claim 7, wherein the carbon capture subsystem includes multiple sorbent chambers configured in an alternating cycle with some chambers in adsorption mode capturing CO₂ from the cooled exhaust gas and at least one chamber in desorption mode being regenerated, permitting continuous carbon capture without interrupting exhaust gas flow.

9. The integrated data center resource system of claim 7, wherein the MOF sorbent is a tetraamine-grafted metal-organic framework that exhibits a step-change in CO₂ adsorption capacity at a threshold temperature or CO₂ concentration, thereby enabling efficient capture at concentration and temperature conditions of the cooled exhaust gas.

10. The integrated data center resource system of claim 1, further comprising an airflow induction device utilizing the Bernoulli principle to enhance cooling or ventilation airflow by leveraging velocity of the hot exhaust stream, the airflow induction device including a venturi-shaped duct that draws in ambient air or data center air when the hot exhaust stream flows through it at high speed.

11. The integrated data center resource system of claim 10, wherein the airflow induction device is configured as an exhaust-driven aspirator that pulls additional ambient air through a condenser of the absorption cooling subsystem or across a cooling coil, thereby increasing heat rejection capacity without requiring an electrically powered fan.

12. The integrated data center resource system of claim 10, wherein the airflow induction device is positioned to draw hot air out of a hot aisle or ceiling plenum of the data center by entraining it into the hot exhaust stream, thereby aiding in expelling heat from the data center using momentum of the hot exhaust stream.

13. The integrated data center resource system of claim 1, wherein the control system is programmed with an optimization algorithm that adjusts at least one of: a split of the hot exhaust stream between the absorption cooling subsystem and the desiccant-based water harvesting subsystem, timing of sorbent regeneration in the carbon capture subsystem, and operation of an airflow induction device, to maximize overall energy efficiency or to prioritize a specific resource output based on real-time demand or environmental conditions.

14. The integrated data center resource system of claim 13, wherein the control system includes sensors for temperature, humidity, and CO₂ concentration and uses feedback from these sensors to dynamically balance the absorption cooling subsystem, desiccant-based water harvesting subsystem, and carbon capture subsystem.

15. The integrated data center resource system of claim 13, wherein the optimization algorithm can operate in multiple modes, including a water maximization mode which intentionally reduces cooling setpoints or uses additional cooling capacity to condense or collect maximum water, and a carbon capture maximization mode which allocates extra heat or time to ensure CO₂ sorbents are fully regenerated to capture maximum carbon.

16. The integrated data center resource system of claim 1, wherein the gas-fired generator is a natural gas microturbine and the integrated data center resource system is sized such that waste heat from the natural gas microturbine is substantially fully utilized by the absorption cooling subsystem and desiccant-based water harvesting subsystem during peak operation, resulting in an overall effective utilization of fuel energy that is higher than in a conventional data center with grid power and mechanical cooling.

17. The integrated data center resource system of claim 1, wherein the gas-fired generator and the absorption cooling subsystem, desiccant-based water harvesting subsystem, and carbon capture subsystem are arranged as a modular unit deployable at data center sites, the modular unit including insulation and noise-abatement for the gas-fired generator, heat exchangers for safe transfer of heat, and quick-connect plumbing for delivering chilled coolant and collected water to data center facilities.

18. A data center facility, comprising:
an integrated system including a gas-fired generator configured to supply electrical power to the data center facility;
an absorption cooling subsystem thermally coupled to a hot exhaust stream of the gas-fired generator;
a desiccant-based water harvesting subsystem receiving at least a portion of the hot exhaust stream;
and a carbon capture subsystem downstream of the absorption cooling subsystem and the desiccant-based water harvesting subsystem,
wherein the data center facility is characterized by a tri-generation plus configuration providing on-site fuel-driven generation, absorption cooling, and water production in one system, and wherein the data center facility draws significantly less utility water and emits significantly less CO₂ than a conventional data center of equivalent IT load.

19. The data center facility of claim 18, further comprising a thermal storage unit connected to the absorption cooling subsystem, configured to store excess heat or cooling during periods of low demand and release it during peak demand, enabling continuous operation of the desiccant-based water harvesting subsystem and carbon capture subsystem even when output from the gas-fired generator fluctuates.

20. An integrated data center and atmospheric water generation system, comprising:
a data center housing computing equipment;
an atmospheric water generation (AWG) system comprising:
a desiccant-based moisture absorption unit configured to extract moisture from air, and
a water separation unit configured to separate water from a moisture-laden desiccant;
wherein exhaust air from the data center is directed as input to the desiccant-based moisture absorption unit of the AWG system;
a liquid cooling system for the data center, comprising a liquid coolant circulated to absorb heat from the computing equipment; and
a heat exchanger coupled between the liquid cooling system and the water separation unit of the AWG system, configured to transfer heat from the liquid coolant, after it has absorbed heat within the data center, to heat the moisture-laden desiccant in the water separation unit, thereby facilitating water extraction from the moisture-laden desiccant.
